(19) United States
(12) Patent Application Publication
(10) Pub. No.: US 2025/0294901 A1
(43) Pub. Date: Sep. 18, 2025

(54) IMAGE SENSOR AND METHOD FOR FABRICATING THE SAME

(71) Applicant: Samsung Electronics Co., Ltd., Suwon-si (KR)

(72) Inventors: Kihyun Kim, Jeonju-si (KR); Hyeongyu Kim, Jeonju-si (KR); Sein Oh, Jeonju-si (KR)

(73) Assignees: Samsung Electronics Co., Ltd., Suwon-si (KR); Industrial Cooperation Foundation Jeonbuk National University, Jeonju-si (KR)

(21) Appl. No.: 19/008,478

(22) Filed: Jan. 2, 2025

(30) Foreign Application Priority Data
Mar. 15, 2024 (KR) 10-2024-0036769

(51) Int. Cl. H10F 39/00

(52) U.S. Cl. CPC H10F 39/8023; H10F 39/011; H10F 39/807

(57) ABSTRACT

Disclosed is an image sensor comprises a substrate region comprising a first surface and a second surface provided opposite to each other, an ion implantation layer provided in the substrate region adjacent to the first surface, a plurality of ion implantation patterns provided in the substrate region of adjacent to the second surface, a first photoelectric conversion region provided adjacent to the ion implantation layer, second electrode patterns provided on the second surface to overlap the ion implantation patterns, first electrode patterns provided between the second electrode patterns, and second photoelectric conversion regions provided adjacent to the first electrode patterns within the substrate region.

### CROSS-REFERENCE TO RELATED APPLICATIONS

The present application claims priority to and the benefit under 35 U.S.C. § 119(a)-(d) to Korean Patent Application No. 10-2024-0036769, filed on Mar. 15, 2024, in the Korean Intellectual Property Office, the entire disclosure of which is incorporated herein by reference.

### BACKGROUND

The present disclosure relates generally to an image sensor and a method of manufacturing the image sensor.

Image sensors are devices that convert optical image signals into electrical signals, and include charge coupled device (CCD) image sensors and complementary metal oxide semiconductor (CMOS) image sensors. The image sensors include a plurality of pixels. Each pixel includes a light-receiving region that receives incident light and converts it into an electrical signal, and a pixel circuit that outputs a pixel signal using charges generated in the light-receiving region.

### SUMMARY

One or more example embodiments provide an image sensor with improved photoelectric conversion efficiency for signals of optical image in near-infrared region.

One or more example embodiments provide a method for fabricating an image sensor with improved photoelectric conversion efficiency for signals of optical image in near-infrared region.

According to some embodiments, an image sensor comprises a substrate region comprising a first surface and a second surface provided on opposite sides of the substrate region, an ion implantation layer provided in the substrate region adjacent to the first surface, a plurality of ion implantation patterns provided in the substrate region, the plurality of ion implantation patterns adjacent to the second surface, a first photoelectric conversion region provided adjacent to the ion implantation layer, second electrode patterns provided on the second surface such that the second electrode patterns overlap the ion implantation patterns, first electrode patterns provided between the second electrode patterns, and second photoelectric conversion regions provided adjacent to the first electrode patterns within the substrate region.

According to some embodiments, a method for manufacturing an image sensor comprises forming an ion implantation layer in a region adjacent to a first surface of a substrate region, forming ion implantation patterns in a region adjacent to a second surface of the substrate region, the second surface of the substrate region located on an opposite side of the substrate region as the first surface, forming second electrode patterns overlapping the ion implantation patterns, and forming first electrode patterns between the second electrode patterns.

According to some embodiments, an image sensor comprises a substrate region, an ion implantation layer provided on an upper portion of the substrate region, a first photoelectric conversion region provided within the substrate region by the ion implantation layer; ion implantation patterns provided at a lower portion of the substrate region, second electrode patterns overlapping the ion implantation patterns, first electrode patterns provided such that the first electrode patterns are electrically spaced apart from the second electrode patterns, and second photoelectric conversion regions provided within the substrate region by the first electrode patterns, a top electrode provided on the upper portion of the substrate region.

Additional aspect will be set forth in part in the description which follows and, in part, will be apparent from the description, or may be learned by practice of the presented embodiments.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a block diagram of an image sensor according to example embodiments.

FIG. 2 is a plan view of the pixel array of FIG. 1, according to some embodiments.

FIG. 3 is an equivalent circuit diagram of the pixel group of FIG. 1, according to some embodiments.

FIG. 4A is a cross-sectional view showing an image sensor according to exemplary embodiments.

FIGS. 4B and 4C are plan views for explaining the image sensor of FIG. 4A, according to some embodiments.

FIG. 5A is a cross-sectional view showing an image sensor according to exemplary embodiments.

FIG. 5B is a plan view for explaining the image sensor of FIG. 5A, according to some embodiments.

FIGS. 6, 7, 8, 9, 10, 11, 12, 13, and 14 are cross-sectional views corresponding to lines A-A′ of FIG. 4A for explaining a method of manufacturing an image sensor according to exemplary embodiments.

FIGS. 15, 16, 17, 18, 19, 20, 21, 22, and 23 are cross-sectional views corresponding to lines B-B′ of FIG. 5 for explaining a method of manufacturing an image sensor according to exemplary embodiments.

FIG. 24 is a cross-sectional view showing an image sensor according to exemplary embodiments.

FIG. 25 is a cross-sectional view showing an image sensor according to exemplary embodiments.

FIG. 26 is a cross-sectional view showing an image sensor according to exemplary embodiments.

FIG. 27 is a cross-sectional view showing an image sensor according to exemplary embodiments.

FIG. 28 is a cross-sectional view showing an image sensor according to exemplary embodiments.

FIG. 29 is a cross-sectional view showing an image sensor according to exemplary embodiments.

FIG. 30 is a cross-sectional view showing the image sensor of FIG. 24 to explain a method of controlling quality factors of nanostructures, according to some embodiments.

### DETAILED DESCRIPTION

Hereinafter, embodiments of the present disclosure will be described clearly and in detail so that a person skilled in the art may easily implement the present disclosure.

Recently, demand for image sensors for detecting signals of an optical image in the near-infrared region has been increased. The signals of an optical image in the near-infrared region can be used in autonomous driving LiDAR sensors, ADAS, CCTV cameras for security, and optical communications.

However, manufacturing the image sensors for detecting the signals of an optical image in the near-infrared region using semiconductor materials (e.g., germanium (Ge), indium antimony (InSb), and indium gallium arsenide (InGaAs)) generally has high-costs and presents low integration density. Accordingly, an image sensor for detecting the signals of optical image in the near-infrared region using a semiconductor material (e.g., silicon (Si)) with excellent economic efficiency and CMOS compatibility is desirable.

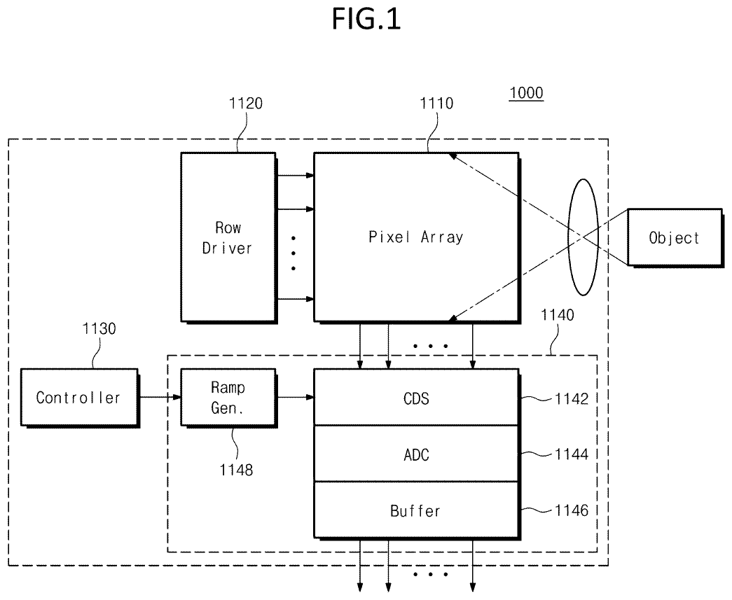

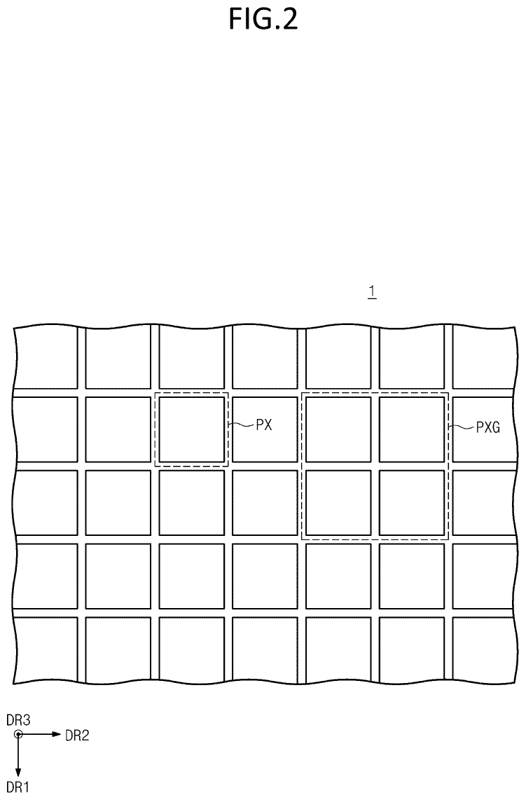

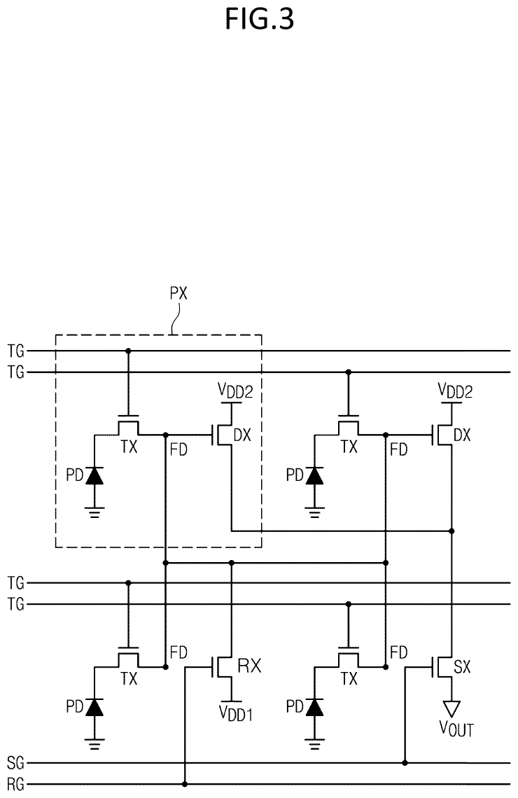

FIG. 1 is a block diagram of an image sensor according to example embodiments. FIG. 2 is a plan view of a pixel array of FIG. 1, according to some embodiments. FIG. 3 is an equivalent circuit diagram of a pixel group of FIG. 1, according to some embodiments.

Referring to FIG. 1, an image sensor 1000 may be provided. The image sensor 1000 may be mounted in an electronic device having an image or light sensing function. For example, the electronic device may be a camera, a smartphone, a wearable device, the Internet of Things (IoT), a tablet PC (Personal Computer), a PDA (Personal Digital Assistant), a PMP (portable multimedia player), or a navigation device. The image sensor 1000 may be mounted in electronic devices provided as components in various devices (e.g., vehicles, furniture, manufacturing facilities, doors, various measuring devices, etc.).

The image sensor 1000 may include a control unit including a pixel array 1110, a controller 1130, a row driver 1120, and a pixel signal processor 1140.

As shown in FIG. 2, the pixel array 1110 may include a plurality of pixels two-dimensionally arranged along a first direction DR1 and a second direction DR2. A plurality of pixels may be arranged in a regular pattern to generate a high-quality image. For example, a plurality of pixels may be arranged in a Bayer pattern or a chess mosaic pattern. When a plurality of pixels have a Bayer pattern, the pixels in the pixel array 1110 may receive red light, green light, and blue light, respectively. In example embodiments, a plurality of pixels may receive cyan light, magenta light, and yellow light. Each of the pixels may include a photoelectric conversion device. The photoelectric conversion device may absorb light to generate charge carriers (electrons or holes). For example, the photoelectric conversion device may include photodiodes, phototransistors, photogates, pinned photodiodes, or a combination thereof. Output voltages of a plurality of pixels may be determined based on the generated charge carriers.

The pixel array 1110 may include a pixel group PXG. The pixel group PXG may be a set of pixels PX sharing a reset transistor RX, a selection transistor SX, and a source follower transistor DX. Although the pixel group PXG is illustrated as being composed of four pixels PX, in example embodiments the pixel group PXG may include less than or more than four pixels PX.

The pixel array 1110 may be driven by receiving a plurality of driving signals, such as a row selection signal, a reset signal, and/or a charge transfer signal, from the row driver 1120. The row driver 1120 may provide a plurality of driving signals to the pixel array 1110 for driving a plurality of pixels. In example embodiments, the driving signals may be provided for each row of the pixel array 1110. Pixels belonging to one row of the pixel array 1110 selected by the driving signals of the row driver 1120 may be simultaneously activated by a signal output from the row driver 1120. The pixels belonging to the selected row may provide output voltages according to absorbed light to output lines of corresponding columns. In example embodiments, the pixels belonging to the selected one row may provide the output voltages together. The output voltages may be provided to correlated double sampler 1142.

The pixel signal processor 1140 may include a correlated double sampler (CDS) 1142, an analog-to-digital converter (ADC) 1144, and a buffer 1146. The correlated double sampler 1142 may sample and hold the output voltages provided by the pixel array 1110. The correlated double sampler 1142 can reduce noise and improve Signal Noise Ratio (SNR). The correlated double sampler 1142 can be configured to remove noise voltages from the output voltages of the pixel. For example, the correlated double sampler 1142 may double sample a specific noise level and a signal level by an output signal, and output a difference level corresponding to a difference between the noise level and the signal level. The correlated double sampler 1142 may output a result based on ramp signals generated by a ramp signal generator 1148.

The analog-to-digital converter 1144 may convert an analog signal corresponding to the difference level received from the correlated double sampler 1142 into a digital signal. The buffer 1146 may latch digital signals, and the latched signals may be sequentially output to the outside of the image sensor 1000 and transferred to an image processor (not shown).

The controller 1130 may control the row driver 1120 so that the pixel array 1110 absorbs light to accumulate charge carriers, temporarily stores the accumulated charge, and outputs an electrical signal according to the accumulated charge to the outside of the pixel array 1110. Also, the controller 1130 may control the pixel signal processor 1140 to measure an output voltage provided by the pixel array 1110.

Referring to FIG. 3, each of a plurality of pixels PX may include a photoelectric conversion device PD, a transfer transistor TX, and a floating diffusion region FD. The photoelectric conversion device PD may generate and accumulate photo charges in proportion to the amount of light incident from the outside, and may include a photodiode, a phototransistor, a photogate, a pinned photodiode, or a combination thereof.

The transfer transistor TX may include a transfer gate TG. The transfer gate TG may transfer charge carriers generated by the photoelectric conversion device PD to the floating diffusion region FD. A transfer control voltage provided from the row driver 1120 may be applied to the transfer gate TG. For example, a channel may be formed between the photoelectric conversion device PD and the floating diffusion region FD by the transfer control voltage applied to the transfer gate TG. Charge carriers generated by the photoelectric conversion device PD may move to the floating diffusion region FD along the channel between the photoelectric conversion device PD and the floating diffusion region FD. A drain terminal of the transfer transistor TX may be electrically connected to the floating diffusion region FD, and a source terminal of the transfer transistor TX may be electrically connected to the photoelectric conversion device PD.

The floating diffusion region FD may receive, accumulate, and store charges generated by the photoelectric conversion device PD. The source follower transistor DX may be controlled according to the amount of charge accumulated in the floating diffusion region FD. A gate terminal of the source follower transistor DX may be electrically connected to the floating diffusion region FD. A second power voltage VDD2 may be applied to a drain terminal of the source follower transistor DX. A source terminal of the source follower transistor DX may be electrically connected to a drain terminal of the selection transistor SX. The source follower transistor DX may be a source follower buffer amplifier that outputs a current proportional to the amount of charge accumulated in the floating diffusion region FD.

The reset transistor RX may periodically reset charges accumulated in the floating diffusion region FD. A gate terminal of the reset transistor RX may be electrically connected to a reset signal line RG. A drain terminal of the reset transistor RX may be connected to the floating diffusion region FD. A first power voltage VDD1 may be applied to a source terminal of the reset transistor RX. In example embodiments, the first power voltage VDD1 may be substantially equal to the second power voltage VDD2. When the reset transistor RX is turned on, the first power voltage VDD1 applied to the source terminal of the reset transistor RX is transferred to the floating diffusion region FD. When the reset transistor RX is turned on, charges accumulated in the floating diffusion region FD are discharged to reset the floating diffusion region FD. When electrons are charge carriers, the voltage of the floating diffusion region FD may decrease as electrons are accumulated in the floating diffusion region FD. When the reset transistor RX is turned on, electrons of the floating diffusion region FD are discharged to the outside, and the voltage of the floating diffusion region FD may increase to the first power voltage VDD1. As the first power voltage VDD1 is applied to the floating diffusion region FD, the first power voltage VDD1 may be applied to the gate terminal of the source follower transistor DX to reset the output of the source follower transistor DX.

The selection transistor SX may select a plurality of pixels PX in each row. The selection transistor SX may transfer current generated by the source follower transistor DX included in each of the selected pixels to an output line (not shown). A drain terminal, a source terminal, and a gate terminal of the selection transistor SX may be electrically connected to the source terminal, the output line, and the row selection line SG of the source follower transistor DX, respectively. A selection control signal applied from the row selection line SG may be applied to the gate terminal of the selection transistor SX to output a signal generated by the source follower transistor DX to the output line.

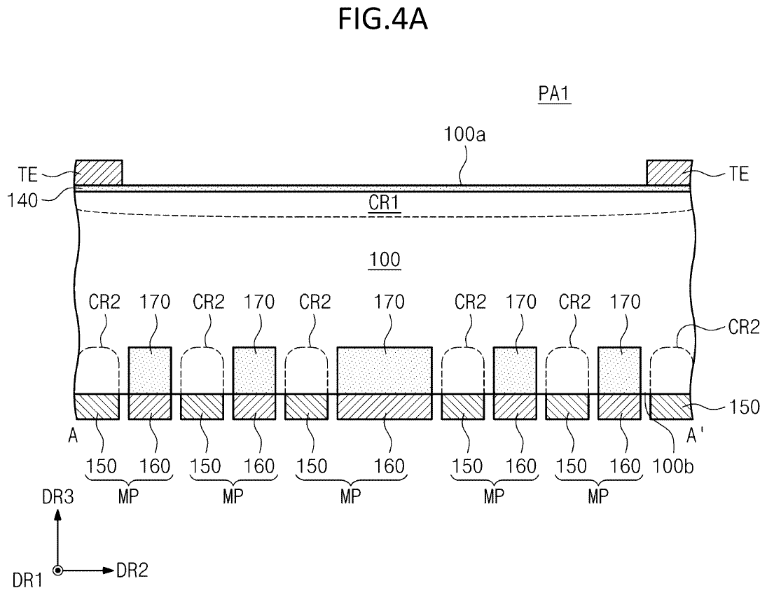

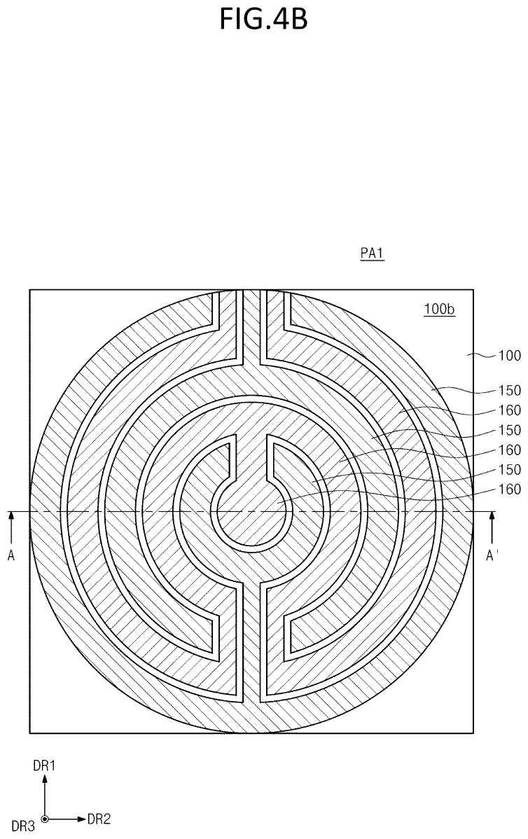

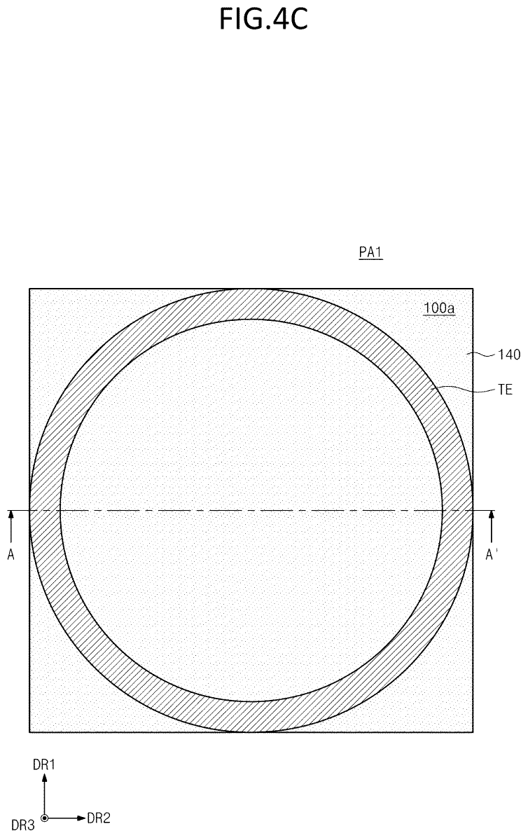

FIG. 4A is a cross-sectional view showing an image sensor according to exemplary embodiments. FIGS. 4B and 4C are plan views for explaining the image sensor of FIG. 4A.

Referring to FIG. 4A, a substrate region 100 may be provided. The substrate region 100 may include a semiconductor material. For example, the substrate region 100 may include silicon (Si), germanium (Ge), or silicon-germanium (Si—Ge). The substrate region 100 may have a first conductivity type. For example, the first conductivity type may be p-type or n-type. When the conductivity type of the substrate region 100 is p-type, the substrate region 100 may be a silicon (Si) region containing a group 3 element or a group 2 element as an impurity. For example, the group 3 element may be boron (B), aluminum (Al), gallium (Ga), or indium (In). When the conductivity type of the substrate region 100 is n-type, the substrate region 100 may be a silicon (Si) region containing a group 5 element, a group 6 element, or a group 7 element as an impurity. For example, the group 5 element may include phosphorus (P), arsenic (As), or antimony (Sb). Hereinafter, impurities that cause the substrate region 100 to have the first conductivity type and the second conductivity type may be referred to as first impurities and second impurities, respectively. When the first conductivity type is p-type or n-type, the second conductivity type may be n-type or p-type, respectively. The substrate region 100 may be an epitaxial layer formed through an epitaxial growth process. For example, the epitaxial layer may be formed by using the epitaxial growth process (e.g., molecular beam epitaxy (MBE), chemical vapor deposition (CVD), or atomic layer deposition (ALD)). The crystal structure of the substrate region 100 may include at least one of single crystal, polycrystal, and amorphous. The substrate region 100 may include a first surface 100a and a second surface 100b facing opposite directions. The first surface 100a and the second surface 100b may be extended along the first direction DR1 and the second direction DR2. The first surface 100a and the second surface 100b may be spaced apart from each other along the third direction DR3. The third direction DR3 may be a direction from the first surface 100a to the second surface 100b. For example, the third direction DR3 may be perpendicular to the first direction DR1 and the second direction DR2.

An ion implantation layer 140 may be provided in a region adjacent to the first surface 100a of the substrate region 100. The ion implantation layer 140 may have the second conductivity type. For example, the ion implantation layer 140 may be a region where the second impurity is implanted into the first surface 100a of the substrate region 100. The concentration of the second impurity implanted into the ion implantation layer 140 may be higher than the concentration of the first impurity implanted into the substrate region 100. The ion implantation layer 140 may be bonded to the substrate region 100 to provide a first photoelectric conversion region CR1. The first photoelectric conversion region CR1 will be described later. For example, the ion implantation layer 140 may be formed by an ion implantation process or a chemical vapor deposition (CVD) process.

Electrode patterns MP may be provided on the second surface 100b of the substrate region 100. The electrode patterns MP may include first electrode patterns 150 and second electrode patterns 160. As shown in FIG. 4B, the first electrode patterns 150 may be arranged along a direction parallel to the first surface 100a (e.g., the first direction DR1, the second direction DR2, or a direction that is a combination of the first direction DR1 and the second direction DR2). From a plan view, the first electrode patterns 150 may have a circular shape. The shape of the first electrode patterns 150 may be determined as needed. For example, from a plan view, the shape of the first electrode patterns 150 may have a square shape, a maze shape, or a cross shape. For brevity of explanation, three first electrode patterns 150 are shown. The number of first electrode patterns 150 may be determined as needed. The first electrode patterns 150 may be provided to be arranged radially from the center of the first electrode patterns 150. The radii of the first electrode patterns 150 may be increased from the center to the edge of the first electrode patterns 150. The radii of the first electrode patterns 150 may be the distance from the center of the electrode patterns MP to the inner sidewall of the first electrode patterns 150. Each of the widths of the first electrode patterns 150 may be substantially equal to each other. The widths of the first electrode patterns 150 may be the distance from the inner sidewalls of the first electrode patterns 150 to the outer sidewalls of the first electrode patterns 160. Each of the thicknesses of the first electrode patterns 150 may be substantially the same as each other. The thicknesses of the first electrode patterns 150 may be the size of the electrode patterns 150 along the third direction DR3. Substantially the same voltage may be applied to the first electrode patterns 150. For example, contacts that apply substantially the same voltage may be provided on the first electrode patterns 150. In exemplary embodiments, voltage may not be applied to the first electrode patterns 150. As an example, two first electrode patterns 150 disposed on the inner side of the three first electrode patterns 150 may be connected to each other by a conductive line therebetween. In other exemplary embodiments, the first electrode patterns 150 may be spaced apart from each other.

When the conductivity type of the substrate region 100 is n-type, the work function of the first electrode patterns 150 may be greater than the work function of the substrate region 100. When the conductivity type of the substrate region 100 is p-type, the work function of the first electrode patterns 150 may be smaller than the work function of the substrate region 100. The work function may be the energy required to emit one charge carrier (e.g., electron) from the first electrode patterns 150. For example, the work function of the substrate region 100 and the first electrode patterns 150 may be determined by the difference between the vacuum level and the fermi level of the substrate region 100 and the first electrode patterns 150. The work function of the substrate region 100 may be determined according to the material and concentration of impurities implanted into the substrate region 100. The work function of the first electrode patterns 150 may be determined according to the material of the first electrode patterns 150. When the substrate region 100 and the first electrode patterns 150 are bonded, the fermi level of the substrate region 100 and the fermi level of the first electrode patterns 150 are in equilibrium with each other, forming a schottky junction. The schottky junction may provide a second photoelectric conversion region CR2. The second photoelectric conversion region CR2 is described later. The first electrode patterns 150 may include an electrically conductive material. Electrically conductive materials may include metals (e.g., magnesium (Mg), chromium (Cr), titanium (Ti), tantalum (Ta), tungsten (W), palladium (Pd), molybdenum (Mo), cobalt (Co), copper (Cu), aluminum (Al), platinum (Pt), silver (Ag), gold (Au), or combinations thereof), transparent metals (e.g., indium tin oxide (ITO), aluminum zinc oxide (AZO), indium zinc oxide (IZO), magnesium oxide (MgO), niobium-doped strontium titanium oxide (Nb:STO), strontium ruthenium oxide (SRO), or combinations thereof), or silicides (e.g., erbium silicide (ErSiₓ), hafnium silicide (HfSiₓ), molybdenum silicide (MoSiₓ), zirconium silicide (ZrSiₓ), titanium silicide (TiSiₓ), cobalt silicide (CoSiₓ), tungsten silicide (WSiₓ), nickel silicide (NiSiₓ), palladium silicide (PdₓSi), platinum silicide (PtSi), or combinations thereof).

The second electrode patterns 160 may be arranged along a direction parallel to the first surface 100a. The second electrode patterns 160 may have a circular shape. The shape of the second electrode patterns 160 may be determined as needed. For example, from a plan view, the shape of the second electrode patterns 160 may have a square shape, a maze shape, or a cross shape. For brevity of explanation, two second electrode patterns 160 are shown. The number of second electrode patterns 160 may be determined as needed. The second electrode patterns 160 may be provided to be arranged radially from the center of the second electrode patterns 160. The radii of the second electrode patterns 160 may be increased from the center to the edge of the second electrode patterns 160. The radii of the second electrode patterns 160 may be the distance from the center of the second electrode patterns 160 to the inner sidewall of the second electrode patterns 160. Each of the widths of the second electrode patterns 160 may be substantially equal to each other. The widths of the second electrode patterns 160 may be the distance from the inner sidewalls of the second electrode patterns 160 to the outer sidewalls of the first electrode patterns 160. Each of the thicknesses of the second electrode patterns 160 may be substantially the same as each other. The thicknesses of the electrode patterns 160 may be the size of the electrode patterns 160 along the third direction DR3. Substantially the same voltage may be applied to the second electrode patterns 160. For example, contacts that apply substantially the same voltage may be provided to the second electrode patterns 160. As an example, two second electrode patterns 150 may be connected to each other by a conductive line therebetween.

Ion implantation patterns 170 may be provided on the second electrode patterns 160. In exemplary embodiments, the ion implantation patterns 170 may be formed by implanting impurities into the substrate region 100. For example, when the conductivity type of the ion implantation patterns 170 is n-type, the work function of the second electrode patterns 160 may be provided to be smaller than the work function of the ion implantation patterns 170. In exemplary embodiments, when the conductivity type of the ion implantation patterns 170 is p-type, the work function of the second electrode patterns 160 may be provided to be greater than the work function of the ion implantation patterns 170. The work function of the second electrode patterns 160 may be determined according to the material of the second electrode patterns 160. The work function of the ion implantation patterns 170 may be determined according to the material and concentration of impurities implanted into the ion implantation patterns 170. When the second electrode patterns 160 and the ion implantation patterns 170 are bonded, the fermi level of the second electrode patterns 160 and the fermi level of the ion implantation patterns 170 are in equilibrium with each other, forming an ohmic contact. The ohmic contact may be provided so that charge carriers (e.g., holes) generated in the second photoelectric conversion region CR2 by incident light are transferred to the second electrode patterns 160. The second electrode patterns 160 may include an electrically conductive material. The electrically conductive materials may include metals (e.g., magnesium (Mg), chromium (Cr), titanium (Ti), tantalum (Ta), tungsten (W), palladium (Pd), molybdenum (Mo), and cobalt (Co), copper (Cu), aluminum (Al), platinum (Pt), silver (Ag), gold (Au), or combinations thereof), transparent metals (e.g., indium tin oxide (ITO), aluminum zinc oxide (AZO), indium zinc oxide (IZO), magnesium oxide (MgO), niobium-doped strontium titanium oxide (Nb:STO), strontium ruthenium oxide (SRO), or combinations thereof), or silicides (e.g., erbium silicide (ErSiₓ), hafnium silicide (HfSiₓ), molybdenum silicide (MoSiₓ), zirconium silicide (ZrSiₓ), titanium silicide (TiSiₓ), cobalt silicide (CoSiₓ), tungsten silicide (WSiₓ), nickel silicide (NiSiₓ), palladium silicide (PdₓSi), platinum silicide (PtSi), or combinations thereof).

The first electrode patterns 150 and second electrode patterns 160 may be arranged radially. For example, the first electrode patterns 150 and the second electrode patterns 160 may include concentric circle-shaped patterns. In exemplary embodiments, the widths of the first electrode patterns 150 may be substantially the same as the widths of the second electrode patterns 160. It is exemplary that the width ratio of the first and second electrode patterns 150 and 160 is 1:1. The width ratio of the first and second electrode patterns 150 and 160 may be determined as needed.

The ion implantation patterns 170 may be provided in a region adjacent to the second surface 100b of the substrate region 100. From a plan view, the shape of the ion implantation patterns 170 may be substantially the same as the shape of the second electrode patterns 160. From a plan view, the ion implantation patterns 170 may have a shape corresponding to the second electrode patterns 160. For example, the ion implantation patterns 170 may be overlapped the second electrode patterns 160 along the third direction DR3. The ion implantation patterns 170 may be provided to form the ohmic contact by bonding with the second electrode patterns 160. The ion implantation patterns 170 may have the first conductivity type. For example, the ion implantation patterns 170 may be regions where the first impurity is implanted into the second surface 100b of the substrate region 100. For example, when the conductivity type of the ion implantation patterns 170 is p-type, the ion implantation patterns 170 may be the silicon (Si) region containing the group 3 element or the group 2 element as the impurity. For example, the group 3 element may be boron (B), aluminum (Al), gallium (Ga), or indium (In). In exemplary embodiments, when the conductivity type of the ion implantation patterns 170 is n-type, the ion implantation patterns 170 are the silicon (Si) region containing the group 5 element, the group 6 element, or the group 7 element as the impurity. For example, the group 5 element may include phosphorus (P), arsenic (As), or antimony (Sb). The concentration of the first or second impurities implanted into the ion implantation patterns 170 may be higher than the concentration of the first or second impurities implanted into the substrate region 100. For example, the ion implantation patterns 170 may be formed by the ion implantation process or the chemical vapor deposition (CVD) process.

Photoelectric conversion regions CR may be provided at an upper portion and a lower portion of the substrate region 100. The photoelectric conversion regions CR may include the first photoelectric conversion region CR1 and the second photoelectric conversion region CR2. The first photoelectric conversion region CR1 may be provided in a region adjacent to the first surface 100a of the substrate region 100. In exemplary embodiments, the first photoelectric conversion region CR1 may be provided by bonding the substrate region 100 and the ion implantation layer 140. For example, when the substrate region 100 is a region containing the first impurity or the second impurity, the ion implantation layer 140 may be a region formed by implanting the second impurity and the first impurity into the first surface 100a of the substrate region 100. For example, the first photoelectric conversion region CR1 may include a pn photodiode. In exemplary embodiments, the p-type region of the first photoelectric conversion region CR1 may be the substrate region 100, and the n-type region of the first photoelectric conversion region CR1 may be the ion implantation layer 140. The p-type and the n-type regions may have a potential gradient due to the p-n junction structure. In some embodiments, the first photoelectric conversion region CR1 includes a pn photodiode. In some embodiments, the first photoelectric conversion region CR1 may include phototransistors or pinned photodiodes. In exemplary embodiments, the second photoelectric conversion region CR2 may be provided in a region adjacent to the second surface 100b of the substrate region 100. From a plan view, the second photoelectric conversion region CR2 may have a shape corresponding to the first electrode patterns 150. From a plan view, the shape of the second photoelectric conversion region CR2 may be substantially the same as the shape of the first electrode patterns 150. For example, the second photoelectric conversion region CR2 may be overlapped the first electrode patterns 150 along the third direction DR3. In exemplary embodiments, the second photoelectric conversion region CR2 may be provided by bonding the substrate region 100 and the first electrode patterns 150. The junction of the substrate region 100 and the first electrode patterns 150 may be referred to the schottky junction. The schottky junction may provide the second photoelectric conversion region CR2.

When light is incident on the photoelectric conversion regions CR, electron-hole pairs may be generated in the photoelectric conversion regions CR. For example, the electron-hole pairs can be generated in a depletion region formed in a region adjacent to a p-n junction. In exemplary embodiments, the electron-hole pairs may be generated in a depletion region formed in a region adjacent to the junction of the first electrode patterns 150 and the substrate region 100. The stronger the intensity of light incident on the photoelectric conversion regions CR, the more electron-hole pairs can be generated. Charge carriers (e.g., electrons) generated in the photoelectric conversion regions CR may be configured to be transferred to a top electrode TE by a voltage applied to the top electrode TE, which will be described later. Charge carriers (e.g., holes) generated in the photoelectric conversion regions CR may be configured to be transferred to the second electrode patterns 160 by a voltage applied to the second electrode patterns 160.

The top electrode TE may be provided on the first surface 100a of the substrate region 100. As shown in FIG. 4C, the top electrode TE may be arranged along a direction parallel to the first surface 100a. From a plan view, the shape of the top electrode TE may be circular. The shape of the top electrode TE can be determined as needed. For example, from a plan view, the shape of the top electrode TE may have a square shape, a maze shape, and a cross shape. For brevity of explanation, one top electrode TE is shown. The number of top electrodes TE can be determined as needed. In exemplary embodiments, from a plan view, the top electrode TE may have a shape corresponding to the electrode pattern MP located at the outermost position among the electrode patterns MP. For example, the top electrode TE may be overlapped the outermost top electrode MP along the third direction DR3. The top electrode TE may be provided to output charge carriers (e.g., electrons) generated in the photoelectric conversion regions CR to the outside. The top electrode TE may include an electrically conductive material. The electrically conductive materials may include metals (e.g., magnesium (Mg), chromium (Cr), titanium (Ti), tantalum (Ta), tungsten (W), palladium (Pd), molybdenum (Mo), cobalt (Co), copper (Cu), aluminum (Al), platinum (Pt), silver (Ag), gold (Au), or combinations thereof), transparent metals (e.g., indium tin oxide (ITO), aluminum zinc oxide (AZO), indium zinc oxide (IZO), magnesium oxide (MgO), niobium-doped strontium titanium oxide (Nb:STO), strontium ruthenium oxide (SRO), or combinations thereof), or silicides (e.g., erbium silicide (ErSiₓ), hafnium silicide (HfSiₓ), molybdenum silicide (MoSiₓ), zirconium silicide (ZrSiₓ), titanium silicide (TiSiₓ), cobalt silicide (CoSiₓ), tungsten silicide (WSiₓ), nickel silicide (NiSiₓ), palladium silicide (PdₓSi), platinum silicide (PtSi), or combinations thereof).

The image sensor PA1 may include the substrate region 100, the ion implantation layer 140, the ion implantation patterns 170, the photoelectric conversion regions CR, the electrode patterns MP, and the top electrode TE.

According to exemplary embodiments of the present disclosure, incident light transmitted to the first photoelectric conversion region CR1 located adjacent to the frontside of the substrate region 100 (i.e., the first surface 100a) and the second photoelectric conversion region CR2 located adjacent to the backside of the substrate region 100 (i.e., the second surface 100b) may generate the electron-hole pairs. For example, the second photoelectric conversion region CR2 may be located at a depth substantially equal to the absorption depth of incident light. Charge carriers (e.g., holes) generated in the region where the second photoelectric conversion region CR2 is formed are not be disappeared and are transferred to the second electrode patterns 160, thereby contributing to the generation of current in the image sensor PA1. Accordingly, the image sensor PA1 with improved photoelectric conversion efficiency can be provided.

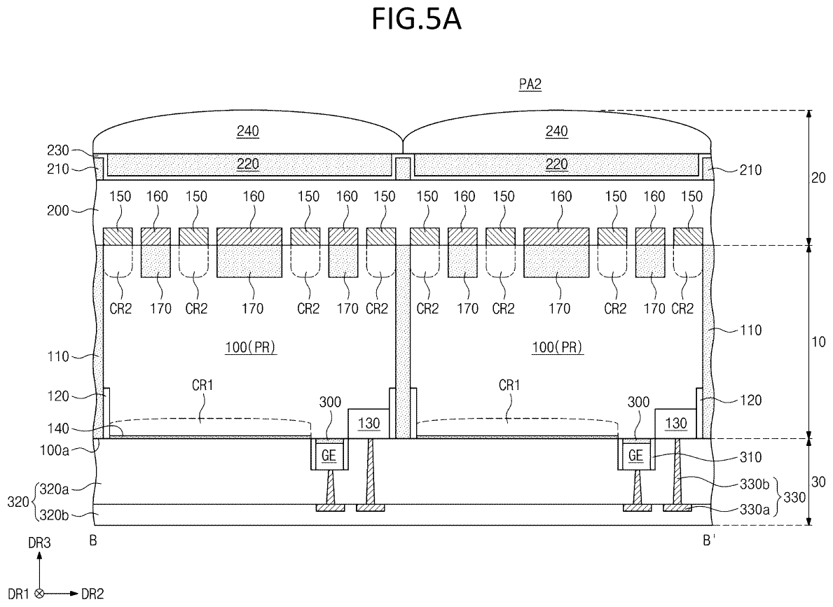

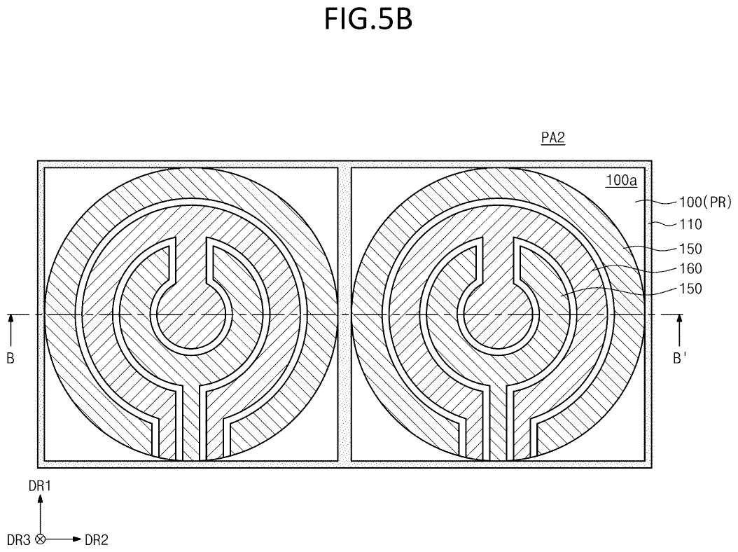

FIG. 5A is a cross-sectional view showing an image sensor according to exemplary embodiments. FIG. 5B is a plan view for explaining the image sensor of FIG. 5A, according to some embodiments.

Referring to FIGS. 5A and 5B, an image sensor PA2 including an element layer 10, an optical element layer 20, and a wiring layer 30 may be provided. The image sensor PA2 may include a plurality of pixels. The image sensor PA2 including two pixels is shown as exemplary. The optical element layer 20 and the wiring layer 30 may be spaced apart from each other with the element layer 10 interposed therebetween. The device layer 10 may include a substrate region 100. The substrate region 100 may include a semiconductor material. For example, the substrate region 100 may include silicon (Si), germanium (Ge), or silicon-germanium (Si—Ge). The substrate region 100 may have a first conductivity type. For example, the first conductivity type may be p-type or n-type. When the conductivity type of the substrate region 100 is p-type, the substrate region 100 may be a silicon (Si) region containing a group 3 element or a group 2 element as an impurity. For example, the group 3 element may be boron (B), aluminum (Al), gallium (Ga), or indium (In). When the conductivity type of the substrate region 100 is n-type, the substrate region 100 may be a silicon (Si) region containing a group 5 element, a group 6 element, or a group 7 element as an impurity. For example, the group 5 element may include phosphorus (P), arsenic (As), or antimony (Sb). The substrate region 100 may be an epitaxial layer formed through an epitaxial growth process. For example, the epitaxial layer may be formed by using an epitaxial growth process (e.g., molecular beam epitaxy (MBE), chemical vapor deposition (CVD), or atomic layer deposition (ALD)). The crystal structure of the substrate region 100 may include at least one of single crystal, polycrystal, and amorphous. The substrate region 100 may include a first surface 100a and a second surface 100b facing opposite directions. The first surface 100a and the second surface 100b may be extended along the first direction DR1 and the second direction DR2.

The device layer 10 may include a pixel isolation layer 110. The pixel isolation layer 110 may define a pixel region PR. The pixel isolation layer 110 may be provided within the substrate region 100. The pixel isolation layer 110 may be extended along the third direction DR3. In one example, the top and bottom surfaces of the pixel isolation layer 110 may be positioned at substantially the same level as the second surface 100b and the first surface 100a, respectively. For example, the pixel isolation layer 110 may be a deep trench isolation (DTI) layer. The pixel isolation layer 110 may be configured to optically and electrically separate adjacent pixels from each other. The pixel isolation layer 110 may have a smaller refractive index than the substrate region 100. The pixel isolation layer 110 prevents or reduces the electrical crosstalk phenomenon that lowers the signal-to-noise ratio (SNR) by exchanging charge carriers between adjacent pixel regions PR. For example, the pixel isolation layer 110 may include an electrically conductive material (e.g., at least one of doped polysilicon, metal, metal silicide, metal nitride, or a metal-containing material), an electrically insulating material (e.g., a silicon-based insulating material (e.g., silicon oxide (SiOₓ), silicon nitride (SiNₓ), and silicon oxynitride (SiOₓN_{y})), or high-k dielectric materials (e.g., metal oxides containing at least one metal selected from the group consisting of hafnium (Hf), zirconium (Zr), aluminum (Al), tantalum (Ta), titanium (Ti), yttrium (Y), and lanthanoid (La)).

In one example, the sidewall of the pixel isolation layer 110 may be doped with a highly reflective material. For example, a highly reflective material may be boron (B). When the pixel isolation layer 110 includes an electrically conductive material, in one example, a negative fixed charge layer may be provided between the pixel isolation layer 110 and the substrate region 100. The negative fixed charge layer may include metal oxides containing at least one metal selected from the group consisting of hafnium (Hf), zirconium (Zr), aluminum (Al), tantalum (Ta), titanium (Ti), yttrium (Y), and lanthanoids (La). The structure of the pixel isolation layer 110 may be determined as needed. In some embodiments, the pixel isolation layer 110 may be an insulating layer having a single-layer structure.

The device layer 10 may include device isolation layers 120. The device isolation layers 120 may be provided adjacent to the first surface 100a. The device isolation layers 120 may be contacted the pixel isolation layers 110 that are immediately adjacent to each other. In exemplary embodiments, the thicknesses of the device isolation layers 120 may be smaller than the thickness of the pixel isolation layer 110. The thicknesses of the device isolation layers 120 may be the sizes of the device isolation layers 120 along the third direction DR3. The device isolation layers 120 may define active regions. From a plan view, the device isolation layers 120 may surround the active regions. The active regions may be regions where gate electrodes GE and floating diffusion regions 130, which will be described later, are provided. For example, the device isolation layers 120 may be shallow trench isolation (STI) layers. Bottom surfaces of the device isolation layers 120 may be located at substantially the same level as the first surface 100a. The device isolation layers 120 may include a silicon-based insulating material. For example, the device isolation layers 120 may include silicon oxide (SiOₓ), silicon nitride (SiNₓ), silicon oxynitride (SiOₓN_{y}), or combinations thereof.

The device layer 10 may include the floating diffusion regions 130. The floating diffusion regions 130 may be provided in each of the pixel regions PR. The floating diffusion regions 130 may be provided within the substrate region 100. The floating diffusion regions 130 may be disposed on one side of the gate electrodes GE. The floating diffusion regions 130 may be disposed adjacent to the first surface 100a. The floating diffusion regions 130 may have the second conductivity type. In some embodiments, the floating diffusion regions 130 may be formed by implanting the second impurity into the substrate region 100. The floating diffusion regions 130 may be spaced apart from the photoelectric conversion regions CR. The region between the floating diffusion regions 130 and the photoelectric conversion regions CR (that is, one region of the substrate region 100) may have the first conductivity type. The floating diffusion regions 130 may receive and accumulate charge carriers provided from the photoelectric conversion regions CR. The floating diffusion regions 130 may function as a drain of a transfer transistor (TX in FIG. 3). The floating diffusion regions 130 may function as a source of a reset transistor (RX in FIG. 3). The floating diffusion regions 130 may be electrically connected to the source follower gate of the source follower transistor (DX in FIG. 3). The source follower transistor (DX in FIG. 3) may be connected to the select transistor (SX in FIG. 3).

The device layer 10 may include an ion implantation layer 140. The ion implantation layer 140 may be provided in each of the pixel regions PR. The ion implantation layer 140 may be provided in a region adjacent to the first surface 100a of the substrate region 100. The ion implantation layer 140 may be disposed on one side of the gate electrodes GE. The ion implantation layer 140 may have the second conductivity type. For example, when the substrate region 100 may be a region where the first impurity is implanted, the ion implantation layer 140 may be a region where the second impurity is implanted. In exemplary embodiments, when the substrate region 100 is a region where the second impurity is implanted, the ion implantation layer 140 may be a region where the first impurity is implanted. When the first conductivity type is p-type or n-type, the second conductivity type may be n-type or p-type, respectively. The concentration of impurities implanted into the ion implantation layer 140 may be higher than the concentration of impurities implanted into the substrate region 100. The ion implantation layer 140 may be bonded to the substrate region 100 to provide a first photoelectric conversion region CR1. The first photoelectric conversion region CR1 will be described later. For example, the ion implantation layer 140 may be formed by an ion implantation process or a chemical vapor deposition (CVD) process.

The device layer 10 may include electrode patterns MP. In exemplary embodiments, each of the pixel regions PR may include the same electrode patterns MP. The electrode patterns MP may be provided on the second surface 100b of the substrate region 100. The electrode patterns MP may include first electrode patterns 150 and second electrode patterns 160. For brevity of explanation, the first electrode pattern 150 and the second electrode pattern 160 included in one pixel region PR are described. As shown in FIG. 5B, the first electrode patterns 150 may be arranged along a direction parallel to the first surface 100a. From a plan view, the first electrode patterns 150 may have a circular shape. The shape of the first electrode patterns 150 may be determined as needed. For example, from a plan view, the shape of the first electrode patterns 150 may have a square shape, a maze shape, or a cross shape. For brevity of explanation, two first electrode patterns 150 are shown. The number of first electrode patterns 150 may be determined as needed. The first electrode patterns 150 may be arranged radially from the center of the first electrode patterns 150. From a plan view, the radii of the first electrode patterns 150 may be increased from the center to the edge of the first electrode patterns 150. The radii of the first electrode patterns 150 may be the distance from the center of the first electrode patterns 150 to the inner sidewalls of the first electrode patterns 150. Each of the widths of the first electrode patterns 150 may be substantially equal to each other. The widths of the first electrode patterns 150 may be the distance from the inner sidewalls of the first electrode patterns 150 to the outer sidewalls of the first electrode patterns 160. Substantially the same voltage may be applied to the first electrode patterns 150. For example, contacts that apply substantially the same voltage may be provided on the first electrode patterns 150.

When the conductivity type of the substrate region 100 is n-type, the work function of the first electrode patterns 150 may be greater than the work function of the substrate region 100. In exemplary embodiments, when the conductivity type of the substrate region 100 is p-type, the work function of the first electrode patterns 150 may be provided to be smaller than the work function of the substrate region 100. The work function may be the energy required to emit one charge carrier (e.g., electron) from the first electrode patterns 150. For example, the work function of the substrate region 100 and the first electrode patterns 150 may be determined by the difference between the vacuum level and the fermi level of the substrate region 100 and the first electrode patterns 150. The work function of the substrate region 100 may be determined according to the material and concentration of impurities implanted into the substrate region 100. The work function of the first electrode patterns 150 may be determined according to the material of the first electrode patterns 150. When the substrate region 100 and the first electrode patterns 150 are bonded, the fermi level of the substrate region 100 and the fermi level of the first electrode patterns 150 are in equilibrium with each other, forming a schottky junction. The schottky junction may provide a second photoelectric conversion region CR2. The second photoelectric conversion region CR2 is described later. The first electrode patterns 150 may include an electrically conductive material. The electrically conductive materials may include metals (e.g., magnesium (Mg), chromium (Cr), titanium (Ti), tantalum (Ta), tungsten (W), palladium (Pd), molybdenum (Mo), cobalt (Co), copper (Cu), aluminum (Al), platinum (Pt), silver (Ag), gold (Au), or combinations thereof), transparent metals (e.g., indium tin oxide (ITO), aluminum zinc oxide (AZO), indium zinc oxide (IZO), magnesium oxide (MgO), niobium-doped strontium titanium oxide (Nb:STO), strontium ruthenium oxide (SRO), or combinations thereof), or silicides (e.g., erbium silicide (ErSiₓ), hafnium silicide (HfSiₓ), molybdenum silicide (MoSiₓ), zirconium silicide (ZrSiₓ), titanium silicide (TiSiₓ), cobalt silicide (CoSiₓ), tungsten silicide (WSiₓ), nickel silicide (NiSiₓ), palladium silicide (PdₓSi), platinum silicide (PtSi), or combinations thereof).

The second electrode pattern 160 may be provided between the first electrode patterns 150. From a plan view, the shape of the second electrode pattern 160 may be circular. The shape of the second electrode pattern 160 may be determined as needed. For example, from a plan view, the shape of the second electrode pattern 160 may have a square shape, a maze shape, or a cross shape. For brevity of explanation, one second electrode pattern 160 is shown. The number of second electrode patterns 160 may be determined as needed. In exemplary embodiments, a plurality of second electrode patterns 160 may be provided in one pixel region PR. For example, a plurality of second electrode patterns 160 having substantially the same width may be provided to be arranged radially from the center of the second electrode patterns 160. The widths of the second electrode patterns 160 may be the distance from the inner sidewalls of the second electrode patterns 160 to the outer sidewalls of the second electrode patterns 160. Substantially the same voltage may be applied to a plurality of second electrode patterns 150. For example, contacts that apply substantially the same voltage may be provided on a plurality of second electrode patterns 150.

Ion implantation patterns 170 may be provided on the bottom surface of the second electrode pattern 160. In exemplary embodiments, the ion implantation patterns 170 may be formed by implanting impurities into the substrate region 100. For example, when the conductivity type of the ion implantation patterns 170 is n-type, the work function of the second electrode patterns 160 may be provided to be smaller than the work function of the ion implantation patterns 170. In exemplary embodiments, when the conductivity type of the ion implantation patterns 170 is p-type, the work function of the second electrode patterns 160 may be provided to be greater than the work function of the ion implantation patterns 170. The work function of the second electrode patterns 160 may be determined according to the material of the second electrode patterns 160. The work function of the ion implantation patterns 170 may be determined according to the impurity material implanted in the ion implantation patterns 170 and the concentration of the impurity. When the second electrode patterns 160 and the ion implantation patterns 170 are bonded, the fermi level of the second electrode patterns 160 and the fermi level of the ion implantation patterns 170 are in equilibrium with each other, forming an ohmic contact. The ohmic contact may be provided so that charge carriers (e.g., holes) generated in the second photoelectric conversion region CR2 by incident light are transferred to the second electrode patterns 160. The second electrode patterns 160 may include an electrically conductive material. The electrically conductive materials may include metals (e.g., magnesium (Mg), chromium (Cr), titanium (Ti), tantalum (Ta), tungsten (W), palladium (Pd), molybdenum (Mo), cobalt (Co), copper (Cu), aluminum (Al), platinum (Pt), silver (Ag), gold (Au), or combinations thereof), transparent metals (e.g., indium tin oxide (ITO), aluminum zinc oxide (AZO), indium zinc oxide (IZO), magnesium oxide (MgO), niobium-doped strontium titanium oxide (Nb:STO), strontium ruthenium oxide (SRO), or combinations thereof), or silicides (e.g., erbium silicide (ErSiₓ), hafnium silicide (HfSiₓ), molybdenum silicide (MoSiₓ), zirconium silicide (ZrSiₓ), titanium silicide (TiSiₓ), cobalt silicide (CoSiₓ), tungsten silicide (WSiₓ), nickel silicide (NiSiₓ), palladium silicide (PdₓSi), platinum silicide (PtSi), or combinations thereof).

The first electrode patterns 150 and the second electrode patterns 160 may be arranged radially. In exemplary embodiments, the widths of the first electrode patterns 150 may be substantially the same as the widths of the second electrode patterns 160. It is exemplary that the width ratio of the first and second electrode patterns 150 and 160 is 1:1. The width ratio of the first and second electrode patterns 150 and 160 may be determined as needed.

The device layer 10 may include the ion implantation patterns 170. The ion implantation patterns 170 may be provided in a region adjacent to the second surface 100b of the substrate region 100. The ion implantation patterns 170 may be overlapped the second electrode patterns 160 along the third direction DR3. From a plan view, the ion implantation patterns 170 may have a shape corresponding to the second electrode patterns 160. For example, from a plan view, the shape of the ion implantation patterns 170 may be substantially the same as the shape of the second electrode patterns 160. The ion implantation patterns 170 may be provided to form the ohmic contact by bonding with the second electrode patterns 160. The ion implantation patterns 170 may have the first conductivity type. For example, the ion implantation patterns 170 may be regions where the first impurity is implanted into the second surface 100a of the substrate region 100. For example, when the conductivity type of the ion implantation patterns 170 is p-type, the ion implantation patterns 170 may be the silicon (Si) region containing the group 3 element or the group 2 element as the impurity. For example, the group 3 element may be boron (B), aluminum (Al), gallium (Ga), or indium (In). In exemplary embodiments, when the conductivity type of the ion implantation patterns 170 is n-type, the ion implantation patterns 170 are the silicon (Si) region containing the group 5 element, the group 6 element, or the group 7 element as the impurity. For example, the group 5 element may include phosphorus (P), arsenic (As), or antimony (Sb). The concentration of the first or the second impurities implanted into the ion implantation patterns 170 may be higher than the concentration of the first or the second impurities implanted into the substrate region 100. For example, the ion implantation patterns 170 may be formed by the ion implantation process or the chemical vapor deposition (CVD) process.

The device layer 10 may include photoelectric conversion regions CR. The photoelectric conversion regions CR may include a first photoelectric conversion region CR1 and a second photoelectric conversion region CR2. The first photoelectric conversion region CR1 may be provided in a region adjacent to the first surface 100a of the substrate region 100. In exemplary embodiments, the first photoelectric conversion region CR1 may be provided by bonding the substrate region 100 and the ion implantation layer 140. For example, when the substrate region 100 is a region containing the first impurity or the second impurity, the ion implantation layer 140 may be a region formed by implanting the second impurity and the first impurity on the first surface 100a of the substrate region 100. For example, the first photoelectric conversion region CR1 may include a pn photodiode. In exemplary embodiments, the p-type region of the first photoelectric conversion region CR1 may be the substrate region 100, and the n-type region of the first photoelectric conversion region CR1 may be the ion implantation layer 140. The p-type and the n-type regions may have a potential gradient due to the p-n junction structure. In some embodiments, the first photoelectric conversion region CR1 includes a pn photodiode. In some embodiments, the first photoelectric conversion region CR1 may include phototransistors or pinned photodiodes.

In exemplary embodiments, the second photoelectric conversion region CR2 may be provided in a region adjacent to the second surface 100b of the substrate region 100. The second photoelectric conversion region CR2 may be overlapped the first electrode patterns 150 along the third direction DR3. From a plan view, the second photoelectric conversion region CR2 may have a shape corresponding to the first electrode patterns 150. For example, from a plan view, the shape of the second photoelectric conversion region CR2 may be substantially the same as the shape of the first electrode patterns 150. The second photoelectric conversion region CR2 may be provided by bonding the substrate region 100 and the first electrode patterns 150. The junction of the substrate region 100 and the first electrode patterns 150 may be referred to the schottky junction.

When light is incident on the device layer 10, electron-hole pairs may be generated. For example, the electron-hole pairs can be generated in the depletion region. In exemplary embodiments, the electron-hole pairs are generated in a depletion region (i.e., the first photoelectric conversion region CR1) formed in a region adjacent to the junction of the substrate region 100 and the ion implantation layer 140 and in a depletion region (i.e., the second photoelectric conversion region CR2) formed in a region adjacent to the junction of the the first electrode patterns 150 and the substrate region 100. The stronger the intensity of light incident on the photoelectric conversion regions CR, the more electron-hole pairs can be generated. Charge carriers (e.g., electrons) generated in the photoelectric conversion regions CR may be configured to be transferred to the floating diffusion regions 130 by a voltage applied to gate electrodes GE, which will be described later. Charge carriers (e.g., holes) generated in the photoelectric conversion regions CR may be configured to be transferred to the second electrode patterns 160 by a voltage applied to the second electrode patterns 160.

The device layer 10 may include the gate electrodes GE. In exemplary embodiments, the gate electrodes GE may be provided in each of the pixel regions PR. The gate electrodes GE may be provided on the first surface 100a of the substrate region 100. The gate electrodes GE may function as gate electrodes GE of different transfer transistors TX, respectively. The gate electrodes GE may include an electrically conductive material. For example, the gate electrodes GE may be polysilicon (e.g., doped polysilicon), metal silicide, or metal (e.g., titanium (Ti), tantalum (Ta), tungsten (W), molybdenum (Mo), cobalt (Co), copper (Cu), aluminum (Al), silver (Ag), gold (Au), platinum (Pt), ruthenium (Ru), titanium nitride (TiN), tungsten nitride (WN), niobium nitride (NbN), or combinations thereof).

The device 10 may include gate insulating layers 300. The gate insulating layers 300 may be provided between the gate electrodes GE and the first surface 100a. In some embodiments, the gate insulating layers 300 may be extended along the surface of the gate electrodes GE facing the first surface 100a to electrically separate the gate electrodes GE from the substrate region 100. For example, the gate insulating layers 300 may include a silicon-based insulating material (e.g., silicon oxide (SiOₓ), silicon nitride (SiNₓ), and silicon oxynitride (SiOₓN_{y})) or a high-k dielectric material (e.g., metal oxides containing at least one metal selected from the group consisting of hafnium (Hf), zirconium (Zr), aluminum (Al), tantalum (Ta), titanium (Ti), yttrium (Y), and lanthanoids (La)).

The device layer 10 may include gate spacers 310. The gate spacers 310 may be provided on sidewalls of the gate electrodes GE. In some embodiments, the gate spacers 310 may be configured to electrically isolate the gate electrodes GE from other components. For example, the gate spacers 310 may include silicon nitride (SiNₓ), silicon carbide Nitride (SiCₓN_{y}), or silicon oxynitride (SiOₓN_{y}).

The optical element layer 20 may include a lower insulating layer 200. The lower insulating layer 200 may be provided on the second surface 100b of the substrate region 100. For example, the lower insulating layer 200 may be configured to protect the lower portion of the substrate region 100. The lower insulating layer 200 may include an electrically insulating material. For example, the lower insulating layer 200 may include silicon oxide (SiOₓ), silicon nitride (SiNₓ), silicon oxynitride (SiOₓN_{y}), germanium oxide (GeOₓ), germanium nitride (GeNₓ), germanium oxynitride (GeOₓN_{y}), or combinations thereof. In exemplary embodiments, the lower insulating layer 200 may be configured to reduce or substantially prevent incident light from being reflected from the second surface 100b of the substrate region 100. For example, the lower insulating layer 200 may include tantalum (Ta) or tantalum nitride (TaN). In exemplary embodiments, the lower insulating layer 200 may have a single-layer structure or a multi-layer structure.

The optical element layer 20 may include a grid 210. The grid 210 may be provided on the lower insulating layer 200. The grid 210 may be provided between color filters 220, which will be described later. The grid 210 may be configured to optically separate color filters 220 that are immediately adjacent to each other. From a plan view, the grid 210 may have a shape corresponding to the pixel isolation layer 110. For example, the grid 210 may be overlapped the pixel isolation layer 110 along the third direction DR3. For example, grid 210 may include an electrically conductive material (e.g., titanium (Ti), titanium nitride (TN)). In exemplary embodiments, the grid 210 may include a low refractive index material with insulating properties. For example, the low refractive index material may include polymer containing nanoparticles (e.g., silica). In exemplary embodiments, the grid 210 may have a single-layer structure or a multi-layer structure of two or more layers.

The optical element layer 20 may include the color filters 220. The color filters 220 may be arranged along a direction parallel to the second surface 100b on the lower insulating layer 200. For example, the color filters 220 may be arranged along the first direction DR1 and the second direction DR2. The color filters 220 may be configured to transmit light in a required wavelength band. In exemplary embodiments, the color filters 220 may transmit red light, green light, or blue light. In exemplary embodiments, the color filters 220 may transmit cyan light, magenta light, and/or yellow light. For example, the color filters 220 may be formed by a dyeing method, a pigment dispersion method, an electrodeposition method, and a printing method. Incident light that has passed through the color filters 220 may be incident on the substrate region 100 corresponding to the color filters 220. In exemplary embodiments, from a plan view, the shape of the color filters 220 may be substantially the same as the shape of the substrate region 100. When a pixel array including a plurality of pixels is provided, the pixel array may include a plurality of color filters 220. The color filters 220 may be arranged along a direction parallel to the second surface 100b on the lower insulating layer 200. The color filters 220 may be configured to transmit light of different wavelength bands.

The optical element layer 20 may include a protective layer 230. The protective layer 230 may be provided between the lower insulating layer 200 and the color filters 220 and between the grid 210 and the color filters 220. For example, the protective layer 230 may be extended conformally along the surfaces of the grid 210 and the lower insulating layer 200. The protective layer 230 may be configured to protect other components from the external environment. The protective layer 230 may include a high-k dielectric material with insulating properties. For example, the protective layer 230 may include aluminum oxide (AlOₓ) or hafnium oxide (HfOₓ).

The optical element layer 20 may include microlens 240. The microlens 240 may be configured to focus incident light and provide it to the substrate region 100. The microlens 240 may have a convex shape along the third direction DR3. The microlens 240 may be overlapped the photoelectric conversion regions CR along the third direction DR3. The microlens 240 may include glass (e.g., silicon-based and chalcogenide-based), thermosetting resin (e.g., polycarbonate-based and polyester-based), and photocurable resin (e.g., acrylic resin-based, epoxy-based, and polyurethane-based), or fluoride-based materials (e.g., CaF₂).

The wiring layer 30 may include wiring insulating layers 320. In exemplary embodiments, the wire insulating layer 300 may include two insulating layers (i.e., a first wire insulating layer 320a and a second wire insulating layer 320b). In other exemplary embodiments, the wire insulation layer 320 may include three or more insulation layers. The first and second wire insulating layers 320a and 320b may include an electrically insulating material. For example, the first and second wiring insulating layers 320a and 320b may include silicon oxide (SiOₓ), silicon nitride (SiNₓ), silicon oxynitride (SiOₓN_{y}), germanium oxide (GeOₓ), and germanium nitride (GeNₓ), germanium oxynitride (GeOₓN_{y}), or combinations thereof.

The wiring layer 30 may include wires 330. The wires 330 may be provided in the first and second wire insulating layers 320a and 320b. The wires 330 may include horizontal wires 330a and vertical wires 330b. The horizontal wires 330a may be extended along a direction parallel to the first surface 100a. The vertical wires 330b may be extended along a direction perpendicular to the first surface 100a (e.g., third direction DR3). The illustrated wires 330 are exemplary. The shape and the number of wires 330 may be determined as needed. The wires 330 may output electrical signals generated in the photoelectric conversion regions CR to the outside. For example, the wires 330 may be provided between the floating diffusion patterns 130 and other electrical components to provide electrical connections between the floating diffusion patterns 130 and other electrical components. The wires 330 may include an electrically conductive material (e.g., metal). For example, the wires 330 may include at least one of titanium (Ti), tantalum (Ta), tungsten (W), molybdenum (Mo), cobalt (Co), copper (Cu), aluminum (Al), silver (Ag), gold (Au), platinum (Pt), ruthenium (Ru), titanium nitride (TiN), tungsten nitride (WN), and niobium nitride (NbN). The wires 330 may be electrically connected to at least one of a transmission gate, a source follower gate, a reset gate, and a selection gate. For example, the wires 330 may be configured to apply the power supply voltage VDD to the drain of the reset transistor RX or the drain of the source follower transistor DX.

The image sensor PA2 may be divided into the element layer 10, the optical element layer 20, and the wiring layer 30. The wiring layer 30 may include the wiring insulating layers 320 and the wires 330. The optical element layer 20 may include the lower insulating layer 200, the grid 210, the color filters 220, the protective layer 230, and the microlens 240. Except for the optical element layer 20 and the wiring layer 30, the remaining components may be included in the device layer 10. In exemplary embodiments, the optical element layer 20 and the wiring layer 30 may be spaced apart from each other with the element layer 10 interposed therebetween. For example, the image sensor PA2 including the optical element layer 20 and the wiring layer 30 spaced apart from each other with the element layer 10 interposed therebetween may be operated in a backside illumination method.

According to exemplary embodiments of the present disclosure, incident light transmitted to the first photoelectric conversion region CR1 located adjacent to the frontside of the substrate region 100 (i.e., the first surface 100a) and the second photoelectric conversion region CR2 located adjacent to the backside of the substrate region 100 (i.e., the second surface 100b) may generate the electron-hole pairs. For example, the second photoelectric conversion region CR2 may be located at a depth substantially equal to the absorption depth of incident light. The charge carriers (e.g., holes) generated in the region where the second photoelectric conversion region CR2 is formed are not disappeared and are transferred to the second electrode patterns 160, thereby contributing to the generation of current in the image sensor PA2. Accordingly, the image sensor PA2 with improved photoelectric conversion efficiency can be provided.

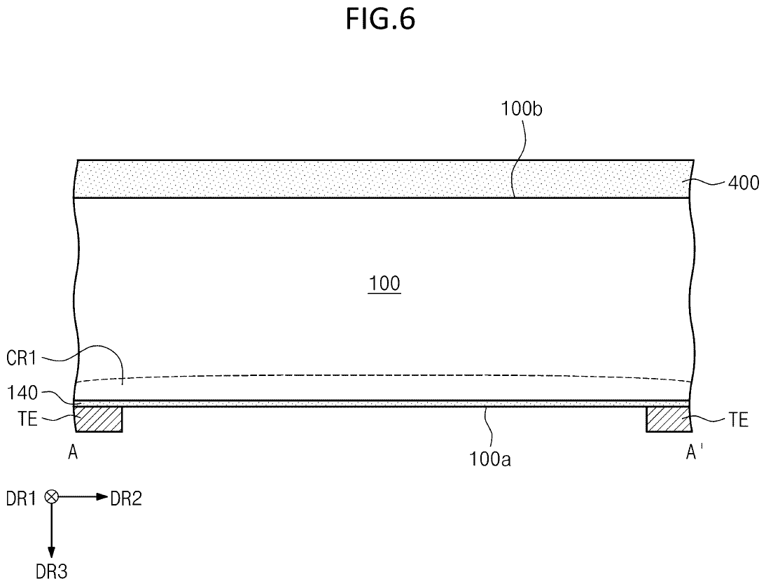

FIGS. 6, 7, 8, 9, 10, 11, 12, 13, and 14 are cross-sectional views corresponding to lines A-A′ of FIG. 4A for explaining a method of manufacturing an image sensor according to some exemplary embodiments. For brevity of explanation, content that is substantially the same as that described with reference to FIGS. 4A, 4B, and 4C may not be described.

Referring to FIG. 6, a first sacrificial layer 400 may be formed on the second surface 100b of the substrate region 100. The first sacrificial layer 400 may include an organic material. For example, the first sacrificial layer 400 may include photoresist. In exemplary embodiments, the first sacrificial layer 400 may be formed by a coating process. For example, the coating process may be performed using a spin-coating method, a spray-coating method, a dip-coating method, an inkjet printing method, or a slot-die coating method.

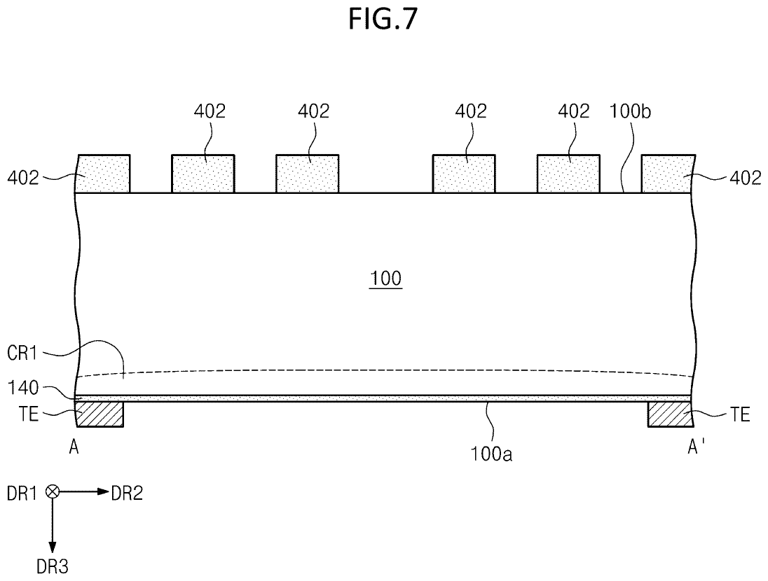

Referring to FIG. 7, the first sacrificial layer 400 may be patterned to form first sacrificial patterns 402. Patterning the first sacrificial layer 400 may include an exposure process of irradiating light to a required region of the first sacrificial layer 400 and a development process of removing either the exposed portion or the unexposed portion. The first sacrificial patterns 402 may be spaced apart from each other. The second surface 100b may be exposed between the first sacrificial patterns 402.

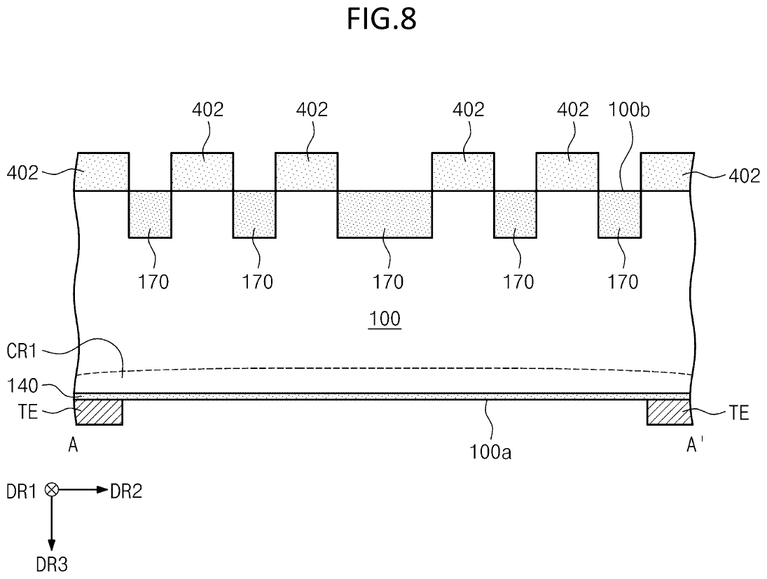

Referring to FIG. 8, ion implantation patterns 170 may be formed in a region adjacent to the second surface 100b of the substrate region 100. The ion implantation patterns 170 may have the first conductivity type same as the substrate region 100. In exemplary embodiments, the ion implantation patterns 170 may be formed by implanting a first impurity into the substrate region 100 exposed between the first sacrificial patterns 402. For example, when the first conductivity type is p-type, the ion implantation patterns 170 may include a group 3 element or a group 2 element as an impurity. For example, the group 3 element may be boron (B), aluminum (Al), gallium (Ga), or indium (In). For example, when the first conductivity type is n-type, the ion implantation patterns 170 may include a group 5 element, a group 6 element, or a group 7 element as an impurity. For example, the group 5 element may be phosphorus (P), arsenic (As), or antimony (Sb). The concentration of the first impurity implanted into the ion implantation patterns 170 may be higher than the concentration of the first impurity contained in the substrate region 100. For example, the ion implantation patterns 170 may be formed by an ion implantation process or a chemical vapor deposition (CVD) process.

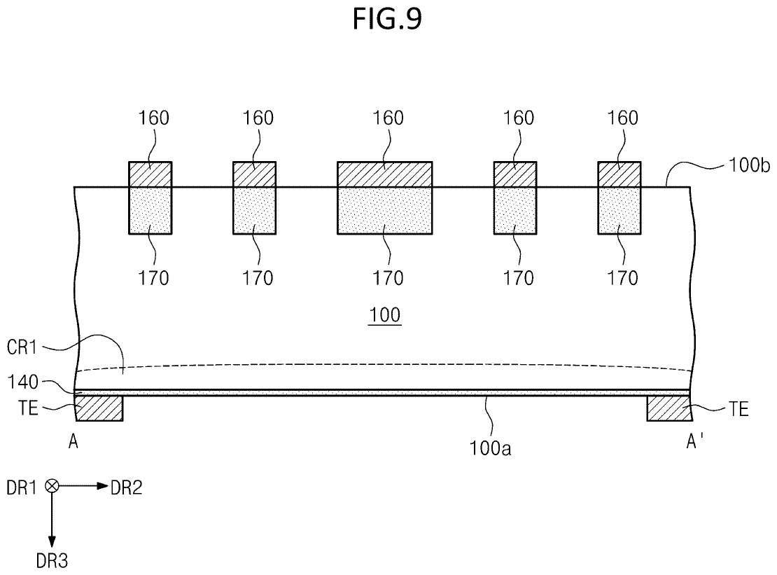

Referring to FIG. 9, second electrode patterns 160 may be formed on each of the ion implantation patterns 170. In exemplary embodiments, the process of forming the second electrode patterns 160 may include depositing an electrically conductive material on the second surface 100b to form an electrically conductive layer covering the first sacrificial patterns 402 and removing the first sacrificial patterns 402 and the electrically conductive layer on the first sacrificial patterns 402. In exemplary embodiments, the process of forming the second electrode patterns 160 may include removing the first sacrificial patterns 402, depositing an electrically conductive material on the second surface 100b to form an electrically conductive layer, and dry etching an electrically conductive layer using a mask pattern. For example, the mask pattern may include an electrically insulating material. For example, depositing the electrically conductive material may be performed using a physical vapor deposition (PVD) process, a chemical vapor deposition (CVD) process, or an atomic layer deposition (ALD) process. For example, electrically conductive materials may include metals (e.g., magnesium (Mg), chromium (Cr), titanium (Ti), tantalum (Ta), tungsten (W), palladium (Pd), molybdenum (Mo), cobalt (Co), copper (Cu), aluminum (Al), platinum (Pt), silver (Ag), gold (Au), or combinations thereof), transparent metals (e.g., indium tin oxide (ITO), aluminum zinc oxide (AZO), indium zinc oxide (IZO), magnesium oxide (MgO), niobium-doped strontium titanium oxide (Nb:STO), strontium ruthenium oxide (SRO), or combinations thereof), or silicides (e.g., erbium silicide (ErSiₓ), hafnium silicide (HfSiₓ), molybdenum silicide (MoSiₓ), zirconium silicide (ZrSiₓ), titanium silicide (TiSiₓ), cobalt silicide (CoSiₓ), tungsten silicide (WSiₓ), nickel silicide (NiSiₓ), palladium silicide (PdₓSi), platinum silicide (PtSi), or combinations thereof).

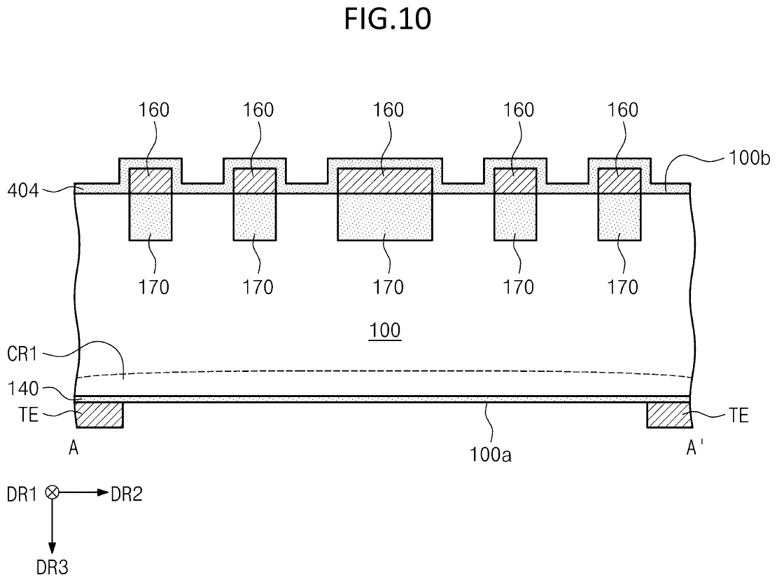

Referring to FIG. 10, a second sacrificial layer 404 may be formed on the second surface 100b. The second sacrificial layer 404 may have a surface profile corresponding to the substrate region 100 and the second electrode patterns 160. For example, the second sacrificial layer 404 may include an electrically insulating material (e.g., a silicon-based insulating material (e.g., silicon oxide (SiOₓ), silicon nitride (SiNₓ), and silicon oxynitride (SiOₓN_{y})), or a high-k dielectric material (e.g., metal oxides containing at least one metal selected from the group consisting of hafnium (Hf), zirconium (Zr), aluminum (Al), tantalum (Ta), titanium (Ti), yttrium (Y), and lanthanoid (La)). In exemplary embodiments, the second sacrificial layer 404 may be formed using physical vapor deposition (PVD) process, chemical vapor deposition (CVD) process, or atomic layer deposition (ALD) process.

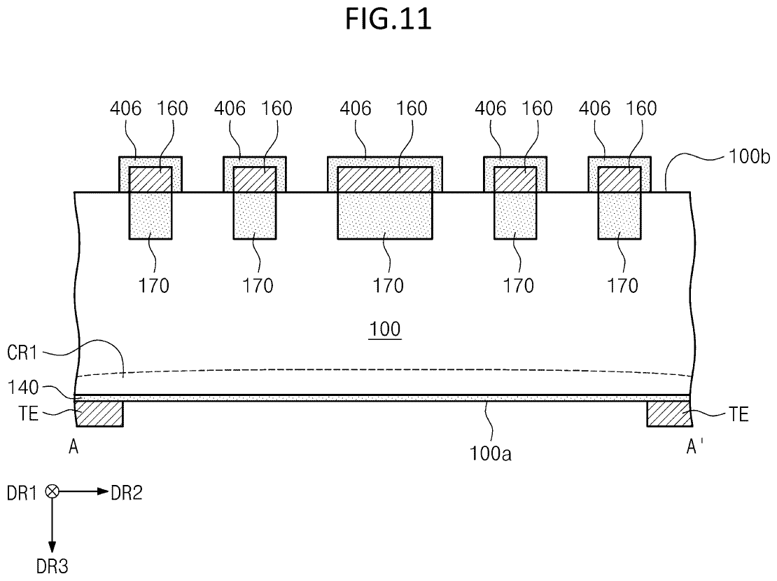

Referring to FIG. 11, the second sacrificial layer 404 may be patterned to form second sacrificial patterns 406. Patterning the second sacrificial layer 404 may include an exposure process of irradiating light to a required region of the photoresist layer (not shown) and a development process of removing either the exposed portion or the unexposed portion. The exposed second sacrificial layer 404 may be etched to form the second sacrificial patterns 406. The second sacrificial patterns 406 may be formed on the second electrode patterns 160. The second sacrificial patterns 406 may be spaced apart from each other.

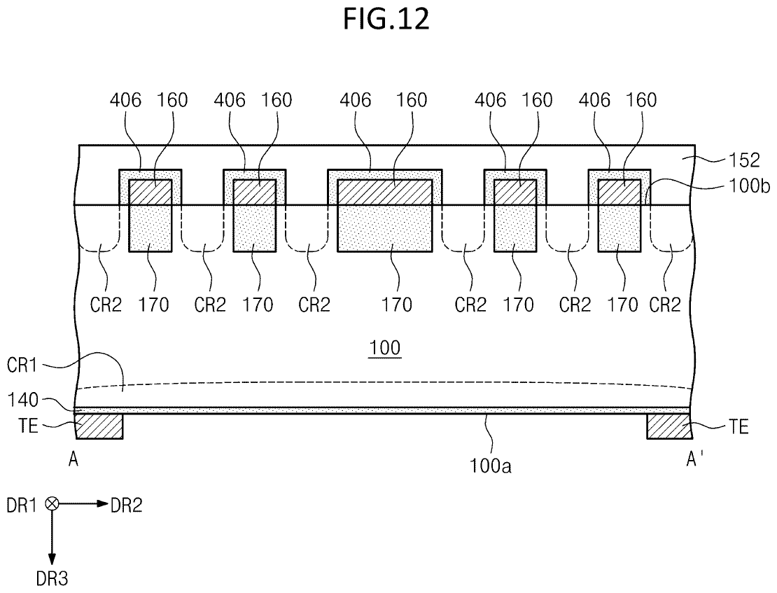

Referring to FIG. 12, a first preliminary electrode layer 152 may be formed on the substrate region 100 and the second sacrificial patterns 406. For example, the first preliminary electrode layer 152 may be formed by depositing an electrically conductive material on the substrate region 100 and the second sacrificial patterns 406. For example, depositing the electrically conductive material may be performed using a physical vapor deposition (PVD) process, a chemical vapor deposition (CVD) process, or an atomic layer deposition (ALD) process. For example, electrically conductive materials may include metals (e.g., magnesium (Mg), chromium (Cr), titanium (Ti), tantalum (Ta), tungsten (W), palladium (Pd), molybdenum (Mo), cobalt (Co), copper (Cu), aluminum (Al), platinum (Pt), silver (Ag), gold (Au), or combinations thereof), transparent metals (e.g., indium tin oxide (ITO), aluminum zinc oxide (AZO), indium zinc oxide (IZO), magnesium oxide (MgO), niobium-doped strontium titanium oxide (Nb:STO), strontium ruthenium oxide (SRO), or combinations thereof), or silicides (e.g., erbium silicide (ErSiₓ), hafnium silicide (HfSiₓ), molybdenum silicide (MoSiₓ), zirconium silicide (ZrSiₓ), titanium silicide (TiSiₓ), cobalt silicide (CoSiₓ), tungsten silicide (Wsiₓ), nickel silicide (NiSiₓ), palladium silicide (PdₓSi), platinum silicide (PtSi), or combinations thereof).

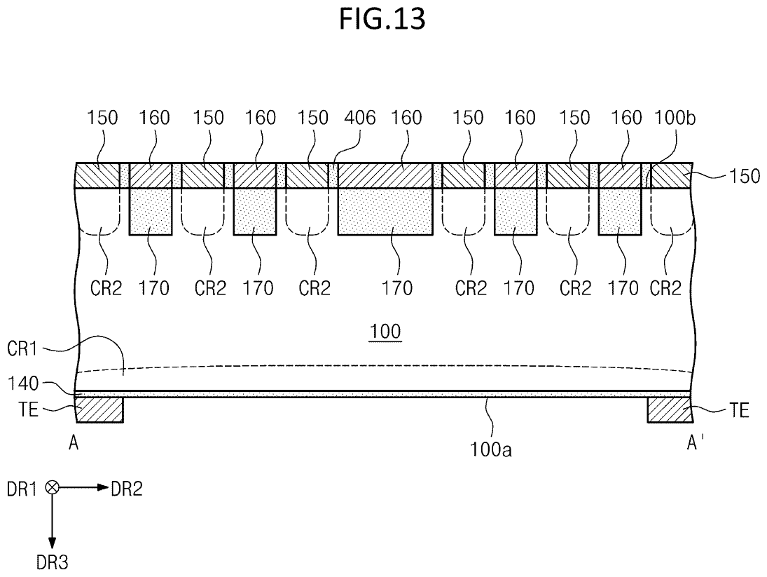

Referring to FIG. 13, first electrode patterns 150 and the second electrode patterns 160 may be formed. In exemplary embodiments, the first electrode patterns 150 and the second electrode patterns 160 may be formed by performing a planarization process on the first preliminary electrode layer 152 and the second sacrificial patterns 406. For example, the planarization process for the first preliminary electrode layer 152 and the second sacrificial patterns 406 may be performed until the top surfaces of the second electrode patterns 160 are exposed. The second sacrificial patterns 406 may be remained between the first electrode patterns 150 and the second electrode patterns 160.

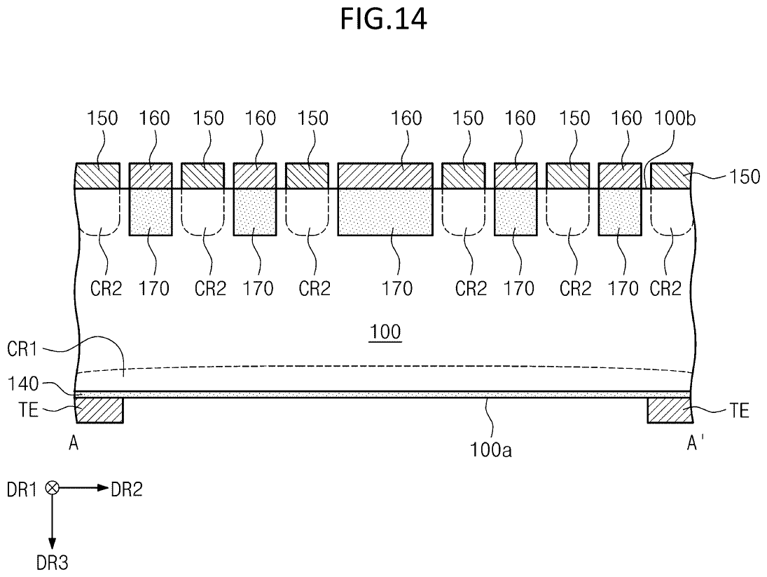

Referring to FIG. 14, the second sacrificial patterns 406 between the first electrode patterns 150 and the second electrode patterns 160 may be removed. For example, the second sacrificial patterns 406 between the first electrode patterns 150 and the second electrode patterns 160 may be removed by a dry etching process. For example, the dry etching process may be performed by a reactive ion etching (RIE) process. The etching gas injected while performing a reactive ion etching (RIE) process may include xenon (Xe), krypton (Kr), argon (Ar), fluorocarbon (CF)-based materials, or combinations thereof.

The present disclosure can provide the method of manufacturing the image sensor PA1 with improved photoelectric conversion efficiency by providing the photoelectric conversion regions CR on the frontside and backside of the substrate region 100, respectively.

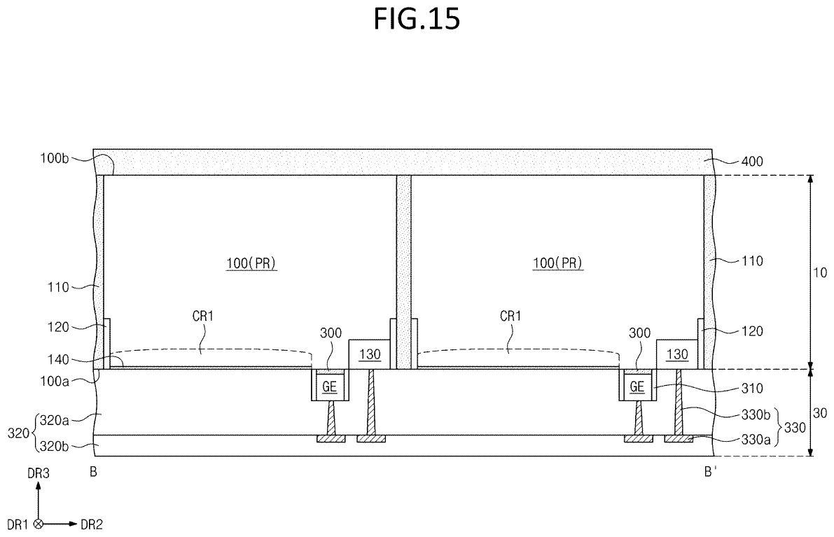

FIGS. 15, 16, 17, 18, 19, 20, 21, 22, and 23 are cross-sectional views corresponding to lines B-B′ of FIG. 5 for explaining a method of manufacturing an image sensor according to some exemplary embodiments. These are the corresponding cross-sectional views. For brevity of explanation, content that is substantially the same as that described with reference to FIGS. 5A, 5B, and C may not be described.

Referring to FIG. 15, the substrate region 100, the pixel isolation layer 110, the device isolation layers 120, the floating diffusion regions 130, the ion implantation layer 140, the first photoelectric conversion region CR1, the gate electrodes GE, the gate insulating layers 300, the gate spacers 310, the wire insulating layers 320, and the wires 330 may be provided.

A first sacrificial layer 400 may be formed on the second surface 100b of the substrate region 100. The first sacrificial layer 400 may include an organic material. For example, the first sacrificial layer 400 may include photoresist. In exemplary embodiments, the first sacrificial layer 400 may be formed by a coating process. For example, the coating process may include a spin-coating method, a spray-coating method, a dip-coating method, an inkjet printing method, or a slot die method. The top surface of the first sacrificial layer 400 may be formed to be substantially parallel to the top surface of the substrate region 100.

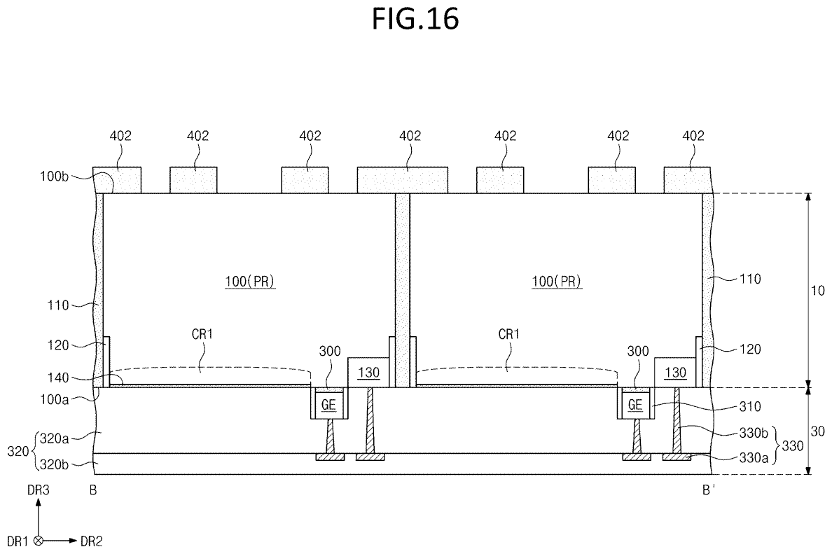

Referring to FIG. 16, the first sacrificial layer 400 may be patterned to form first sacrificial patterns 402. Patterning the first sacrificial layer 400 may include an exposure process of irradiating light to a required region of the first sacrificial layer 400 and a development process of removing either the exposed portion or the unexposed portion. The first sacrificial patterns 402 may be spaced apart from each other.

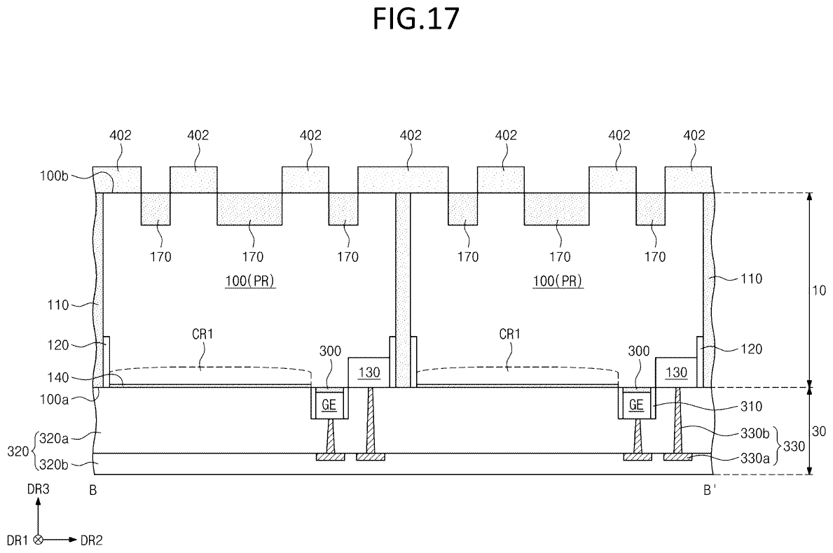

Referring to FIG. 17, ion implantation patterns 170 may be formed in a region adjacent to the second surface 100b of the substrate region 100. The ion implantation patterns 170 may have the first conductivity type same as the substrate region 100. In exemplary embodiments, the ion implantation patterns 170 may be formed by implanting a first impurity into the substrate region 100 exposed between the first sacrificial patterns 402. For example, when the first conductivity type is p-type, the ion implantation patterns 170 may include a group 3 element or a group 2 element as an impurity. For example, the group 3 element may be boron (B), aluminum (Al), gallium (Ga), or indium (In). For example, when the first conductivity type is n-type, the ion implantation patterns 170 may include a group 5 element, a group 6 element, or a group 7 element as an impurity. For example, the group 5 element may be phosphorus (P), arsenic (As), or antimony (Sb). The concentration of the first impurity implanted into the ion implantation patterns 170 may be higher than the concentration of the first impurity implanted in the substrate region 100. For example, the ion implantation patterns 170 may be formed by an ion implantation process or a chemical vapor deposition (CVD) process.

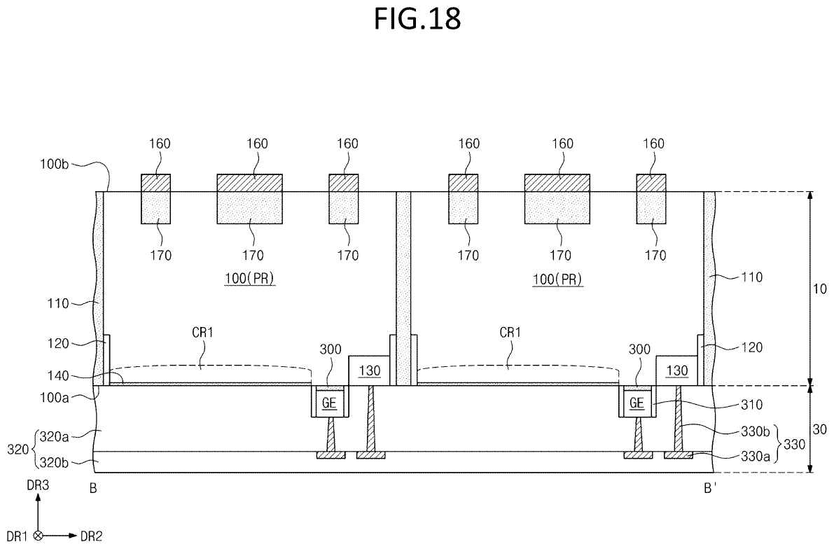

Referring to FIG. 18, second electrode patterns 160 may be formed on each of the ion implantation patterns 170. In exemplary embodiments, the process of forming the second electrode patterns 160 may include depositing an electrically conductive material on the second surface 100b to form an electrically conductive layer covering the first sacrificial patterns 402 and removing the first sacrificial patterns 402 and the electrically conductive layer on the first sacrificial patterns 402. In exemplary embodiments, the process of forming the second electrode patterns 160 may include removing the first sacrificial patterns 402, depositing an electrically conductive material on the second surface 100b to form an electrically conductive layer and dry etching an electrically conductive layer using a mask pattern. For example, the mask pattern may include an electrical insulating layer. For example, electrically conductive materials may include metals (e.g., magnesium (Mg), chromium (Cr), titanium (Ti), tantalum (Ta), tungsten (W), palladium (Pd), molybdenum (Mo), cobalt (Co), copper (Cu), aluminum (Al), platinum (Pt), silver (Ag), gold (Au), or combinations thereof), transparent metals (e.g., indium tin oxide (ITO), aluminum zinc oxide (AZO), indium zinc oxide (IZO), magnesium oxide (MgO), niobium-doped strontium titanium oxide (Nb:STO), strontium ruthenium oxide (SRO), or combinations thereof), or silicides (e.g., erbium silicide (ErSiₓ), hafnium silicide (HfSiₓ), molybdenum silicide (MoSiₓ), zirconium silicide (ZrSiₓ), titanium silicide (TiSiₓ), cobalt silicide (CoSiₓ), tungsten silicide (WSiₓ), nickel silicide (NiSiₓ), palladium silicide (PdₓSi), platinum silicide (PtSi), or combinations thereof).

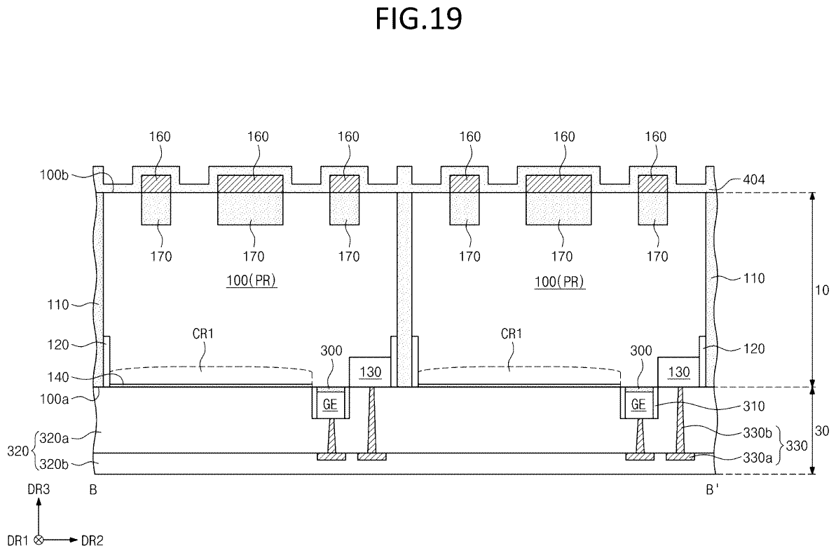

Referring to FIG. 19, a second sacrificial layer 404 may be formed on the second surface 100b. The second sacrificial layer 404 may have a surface profile corresponding to the substrate region 100 and the second electrode patterns 160. For example, the second sacrificial layer 404 may include an electrically insulating material (e.g., a silicon-based insulating material (e.g., silicon oxide (SiOₓ), silicon nitride (SiNₓ), and silicon oxynitride (SiOₓN_{y})), or high-k materials (e.g., metal oxides containing at least one metal selected from the group consisting of hafnium (Hf), zirconium (Zr), aluminum (Al), tantalum (Ta), titanium (Ti), yttrium (Y), and lanthanoid (La)). In exemplary embodiments, the second sacrificial layer 404 may be formed using a physical vapor deposition (PVD) process, a chemical vapor deposition (CVD) process, or an atomic layer deposition (ALD) process.

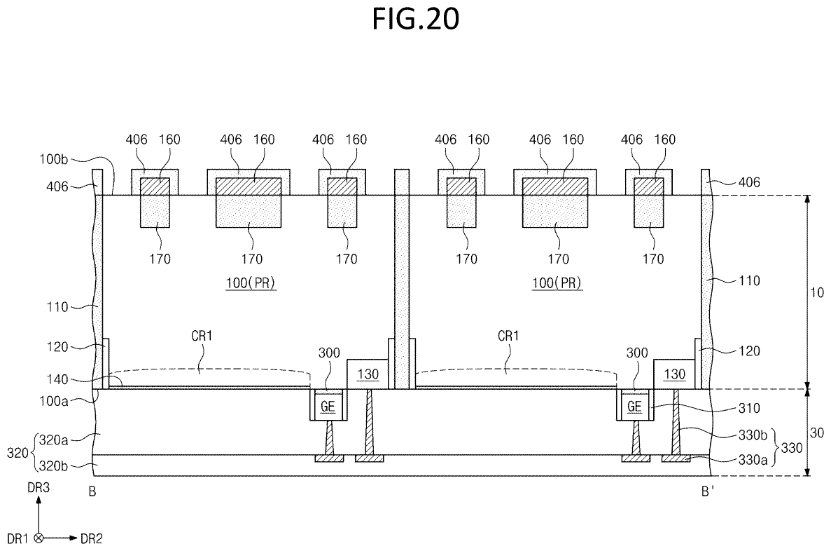

Referring to FIG. 20, the second sacrificial layer 404 may be patterned to form second sacrificial patterns 406. Patterning the second sacrificial layer 404 may include an exposure process of irradiating light to a required region of the photoresist layer (not shown) and a development process of removing either the exposed portion or the unexposed portion. The exposed second sacrificial layer 404 may be etched to form the second sacrificial patterns 406. The second sacrificial patterns 406 may be formed on the second electrode patterns 160. The second sacrificial patterns 406 may be spaced apart from each other.

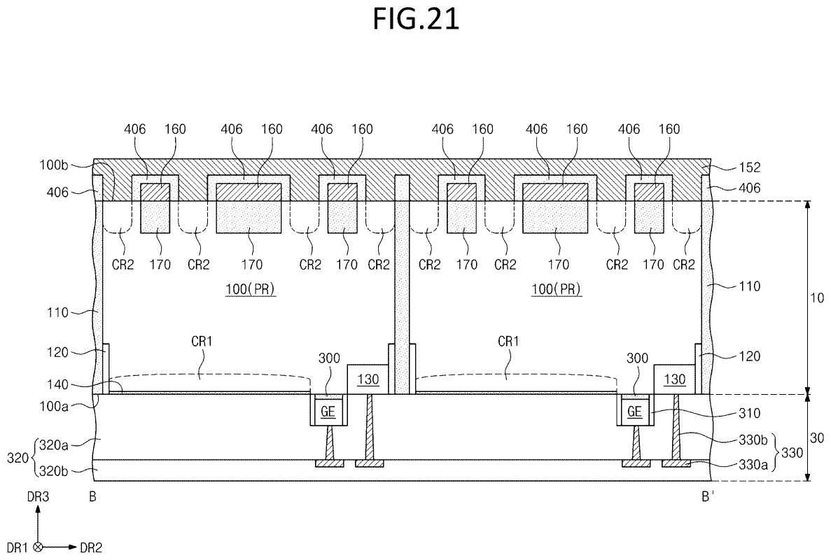

Referring to FIG. 21, a first preliminary electrode layer 152 may be formed on the substrate region 100 and the second sacrificial patterns 406. For example, the first preliminary electrode layer 152 may be formed by depositing an electrically conductive material on the substrate region 100 and the second sacrificial patterns 406. For example, depositing the electrically conductive material may be performed using a physical vapor deposition (PVD) process, a chemical vapor deposition (CVD) process, or an atomic layer deposition (ALD) process. For example, electrically conductive materials may include metals (e.g., magnesium (Mg), chromium (Cr), titanium (Ti), tantalum (Ta), tungsten (W), palladium (Pd), molybdenum (Mo), cobalt (Co), copper (Cu), aluminum (Al), platinum (Pt), silver (Ag), gold (Au), or combinations thereof), transparent metals (e.g., indium tin oxide (ITO), aluminum zinc oxide (AZO), indium zinc oxide (IZO), magnesium oxide (MgO), niobium-doped strontium titanium oxide (Nb:STO), strontium ruthenium oxide (SRO), or combinations thereof), or silicides (e.g., erbium silicide (ErSiₓ), hafnium silicide (HfSiₓ), molybdenum silicide (MoSiₓ), zirconium silicide (ZrSiₓ), titanium silicide (TiSiₓ), cobalt silicide (CoSiₓ), tungsten silicide (WSiₓ), nickel silicide (NiSiₓ), palladium silicide (PdₓSi), platinum silicide (PtSi), or combinations thereof).

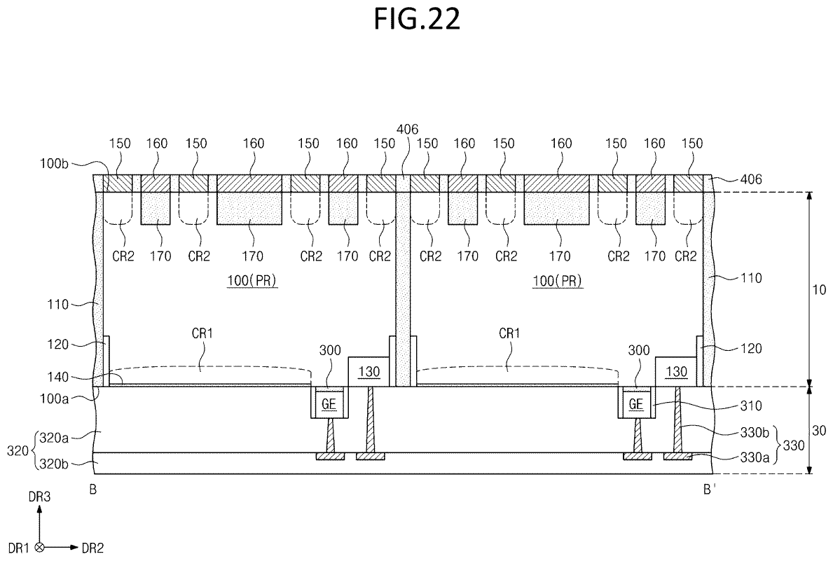

Referring to FIG. 22, first electrode patterns 150 and the second electrode patterns 160 may be formed. In exemplary embodiments, the first electrode patterns 150 and the second electrode patterns 160 are formed by performing a planarization process on the first preliminary electrode layer 152 and the second sacrificial patterns 406. For example, the planarization process for the first preliminary electrode layer 152 and the second sacrificial patterns 406 may be performed until the top surfaces of the second electrode patterns 160 are exposed. The second sacrificial patterns 406 may be remained between the first electrode patterns 150 and the second electrode patterns 160. For example, the second sacrificial patterns 406 may be remained on the second surface 100b between the first electrode patterns 150 and the second electrode patterns 160 and on the pixel isolation layer 110.

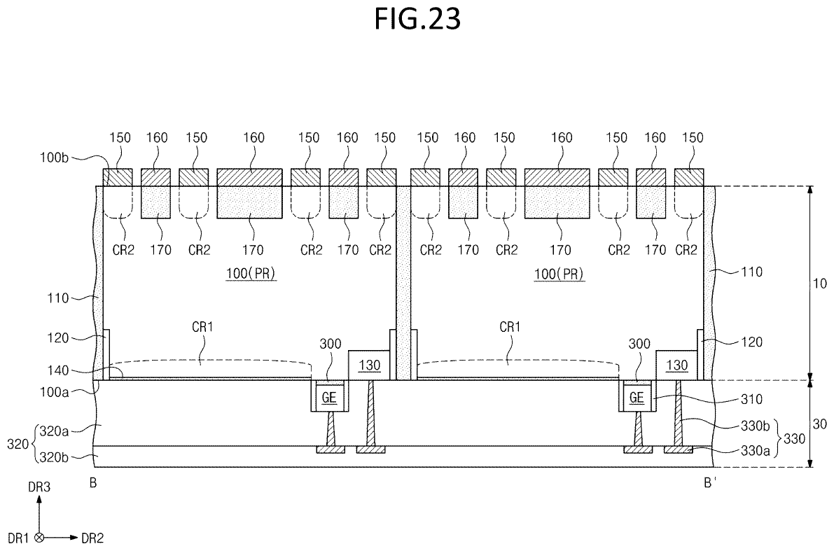

Referring to FIG. 23, the second sacrificial patterns 406 between the first electrode patterns 150 and the second electrode patterns 160 may be removed. For example, the second sacrificial patterns 406 between the first electrode patterns 150 and the second electrode patterns 160 may be removed by a dry etching process. For example, the dry etching process may be performed by a reactive ion etching (RIE) process. The etching gas injected while performing the reactive ion etching process (RIE) may include xenon (Xe), krypton (Kr), argon (Ar), fluorocarbon (CF)-based materials, or combinations thereof. Accordingly, the pixel isolation layer 110 and the second surface 100b between the first electrode patterns 150 and the second electrode patterns 160 may be exposed.

Referring to FIGS. 5A and 5B, the lower insulating layer 200, the grid 210, the color filters 220, and the protective layer 230, and the microlens 240 may be formed on the first electrode patterns 150 and the second electrode patterns 160.

The present disclosure may provide the method of manufacturing the image sensor PA2 with improved photoelectric conversion efficiency by providing the photoelectric conversion regions CR on the frontside and backside of the substrate region 100, respectively.

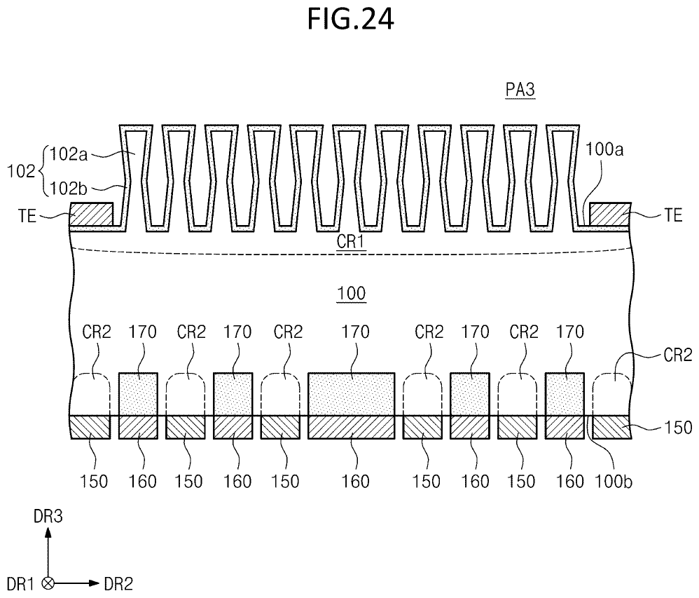

FIG. 24 is a cross-sectional view showing an image sensor according to some exemplary embodiments. For brevity of explanation, content that is substantially the same as that described with reference to FIGS. 4A, 4B, and 4C may not be described.

Referring to FIG. 24, an image sensor PA3 may be provided. Unlike those described with reference to FIGS. 4A, 4B, and 4C, nanostructures 102 may be provided on the first surface 100a of the substrate region 100. The nanostructures 102 may include a vertical nanocore 102a and a vertical nanoshell 102b. The vertical nanocore 102a may be extended from the first surface 100a of the substrate region 100 along the third direction DR3. For example, the vertical nanocore 102a may be a region formed by etching the upper portion of the substrate region 100. The vertical nanocore 102a and the substrate region 100 may be formed as a single structure. For example, the vertical nanocore 102a and the substrate region 100 may be connected to each other without an interface therebetween.

The vertical nanoshell 102b may be extended conformally along the top and side surfaces of the vertical nanocore 102a. The width of the vertical nanocore 102a may be greater than the thickness of the vertical nanoshell 102b. The width of the vertical nanocore 102a may be the size of the vertical nanocore 102a along the second direction DR2. The thickness of the vertical nanoshell 102b may be the size of the vertical nanoshell 102b along the second direction DR2. In exemplary embodiments, the sum of the thicknesses of the substrate region 100 and the nanostructures 102 may be configured to be substantially equal to the absorption depth of incident light. The thicknesses of the substrate region 100 and the nanostructures 102 may be the sizes of the substrate region 100 and the nanostructures 102 along the third direction DR3. The absorption depth can be determined by the Beer-Lambert law (Equation 1). The absorption coefficient can be provided to decrease as the wavelength of incident light becomes longer. The absorption depth can be provided to be longer as the wavelength of incident light becomes longer.

$$l = {α}^{- 1} log ( \frac{{I}_{0}}{I} ) \qquad Equation 1$$

(l: absorption depth, α: absorption coefficient, I: intensity of incident light incident on the first surface 100a, and I₀: intensity of incident light transmitting the second surface 100b)

For brevity of explanation, 11 nanostructures 102 are illustrated. The number of nanostructures 102 may be determined as needed. It is exemplary that the nanostructures 102 are configured in an hourglass shape. The shape of the nanostructures 102 may be determined as needed. For example, the shape of the nanostructures 102 may have at least one of a cylinder shape, a cone shape, an inverted cone shape, a honeycomb shape, and a pyramid shape. From a plan view, the nanostructures 102 may be provided to be surrounded by the top electrode TE.

The nanostructures 102 may be provided to generate electron-hole pairs by incident light. In exemplary embodiments, when the vertical nanocore 102a is a semiconductor region containing a first impurity, the vertical nanoshell 102b may be a semiconductor region formed by implanting a second impurity into the top and side surfaces of the vertical nanocore 102a. The concentration of the first impurity included in the vertical nanocore 102a may be lower than the concentration of the second impurity implanted into the vertical nanoshell 102b. As the vertical nanoshell 102b has a different conductivity type from the vertical nanocore 102a and the substrate region 100, a first photoelectric conversion region CR1 may be provided. For example, the first photoelectric conversion region CR1 may include a pn photodiode. For example, a p-type region of the first photoelectric conversion region CR1 may be the vertical nanocore 102a, and a n-type region may be the vertical nanoshell 102b. In exemplary embodiments, the p-type region of the first photoelectric conversion region CR1 may be the substrate region 100, and the n-type region may be the vertical nanoshell 102b. The p-type and the n-type regions may have a potential gradient due to the p-n junction structure. For example, the vertical nanoshell 102b may be formed by an ion implantation process or a chemical vapor deposition (CVD) process.

In exemplary embodiments, the nanostructures 102 may have a lower portion with a width that gradually decreases along the third direction DR3 and an upper portion that has a width that gradually increases along the third direction DR3. The width of the nanostructures 102 may be the size of the nanostructures 102 along the second direction DR2. For example, the upper portions of the nanostructures 102 may be configured so that light incident on the upper portions of the nanostructures 102 may generate whispering gallery modes (WGM) resonance. The whispering gallery mode resonance may be a phenomenon in which the intensity of electromagnetic waves (e.g., light or sound) are increased when electromagnetic waves (e.g., light or sound) are overlapped. The upper portions of the nanostructures 102 may be provided to increase the effective length of incident light transmitting the nanostructures 102 by whispering gallery mode resonance. The lower portions of the nanostructures 102 may be configured to absorb incident light reflected from the nanostructures 102 immediately adjacent to each other.

The electron-hole pairs generated by incident light in the nanostructures 102 may be transferred to the substrate region 100 along the nanostructures 102. An electric field may be provided by a voltage applied to the top electrode TE and the second electrode patterns 160. For example, the electric field may be formed in a direction from the first surface 100a to the second surface 100b. The direction in which the electron-hole pairs generated by incident light in the nanostructures 102 are transferred to the top electrode TE and the second electrode patterns 160 may be substantially the same as the direction of the electric field. The electron-hole pairs generated in the nanostructures 102 of the present disclosure may be transferred to the top electrode TE and the second electrode patterns 160 without disappearing.

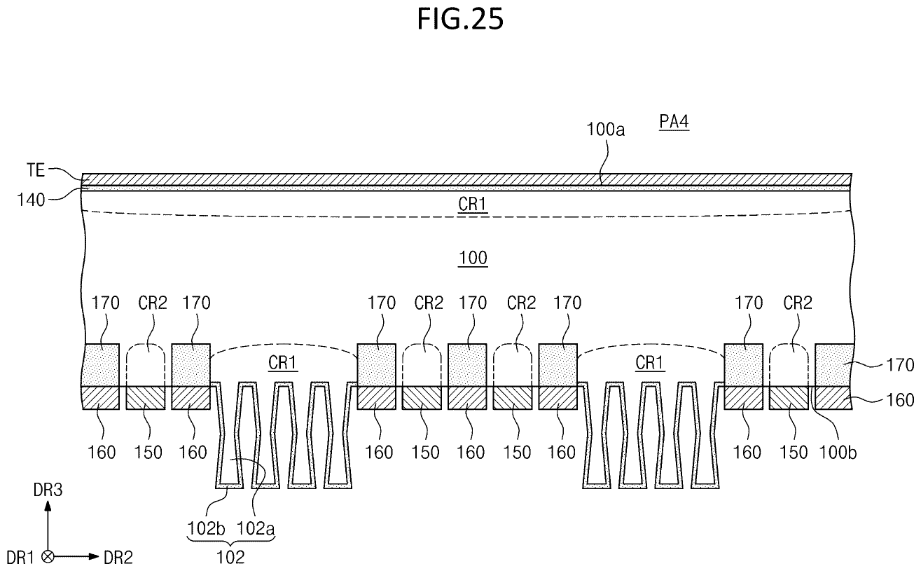

FIG. 25 is a cross-sectional view showing an image sensor according to some exemplary embodiments. For brevity of explanation, content that is substantially the same as that described with reference to FIGS. 4A, 4B, and 4C and that described with reference to FIG. 24 may not be described.

Referring to FIG. 25, an image sensor PA4 may be provided. Unlike those described with reference to FIGS. 4A, 4B, and 4C, nanostructures 102 may be provided on the second surface 100b of the substrate region 100. The nanostructures 102 may be substantially the same as the nanostructures 102 described with reference to FIG. 24 except for their provision locations. The nanostructures 102 may be provided on the second surface 100b. The nanostructures 102 may be provided between the second electrode patterns 160 that are immediately adjacent to each other. Accordingly, a first photoelectric conversion region CR1 may be provided between the second electrode patterns 160 that are immediately adjacent to each other. For brevity of explanation, four nanostructures 102 are illustrated between the second electrode patterns 160 immediately adjacent to each other. The number of nanostructures 102 may be determined as needed.

Electron-hole pairs generated by incident light in the nanostructures 102 may be configured to be transferred in the third direction DR3 along the shape of the nanostructures 102. An electric field may be provided by a voltage applied to the top electrode TE and the second electrode patterns 160. The direction of the electric field may be provided in the third direction DR3. The direction in which the electron-hole pairs generated by incident light in the nanostructures 102 are transferred to the top electrode TE and the second electrode patterns 160 may be substantially the same as the direction of the electric field. The electron-hole pairs generated in the nanostructures 102 may be transferred to the top electrode TE and the second electrode patterns 160 without disappearing. From a plan view, electrode patterns MP may be provided to surround the nanostructures 102.

A top electrode TE may be provided on the first surface 100a of the substrate region 100. The top electrode TE may be provided to cover the first surface 100a of the substrate region 100. The top electrode TE may include an electrically conductive material. Electrically conductive materials may include transparent metals (e.g., indium tin oxide (ITO), aluminum zinc oxide (AZO), indium zinc oxide (IZO), magnesium oxide (MgO), and niobium-doped strontium titanium oxide (Nb:STO), strontium ruthenium oxide (SRO), or combinations thereof).

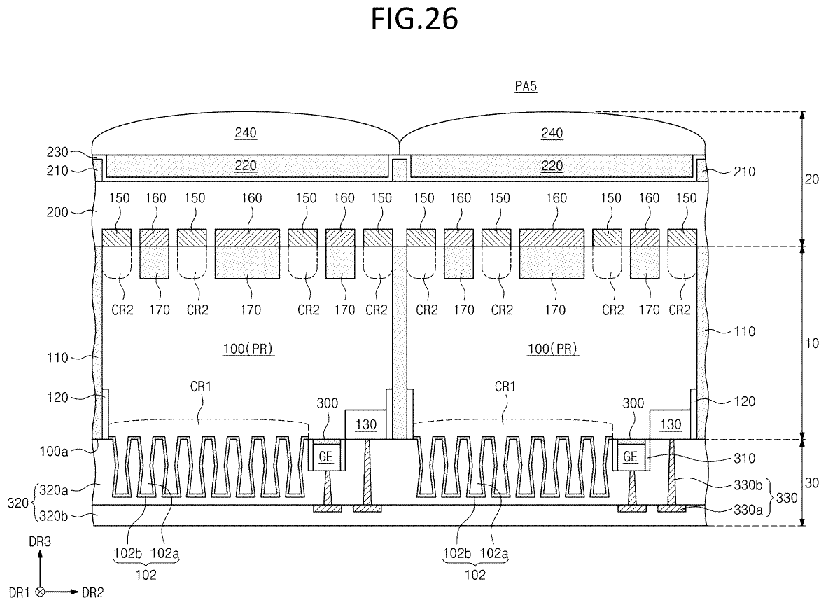

FIG. 26 is a cross-sectional view showing an image sensor according to some exemplary embodiments. For brevity of explanation, content that is substantially the same as that described with reference to FIGS. 5A and 5B and that described with reference to FIG. 24 may not be described.

Referring to FIG. 26, an image sensor PA5 may be provided. Unlike those described with reference to FIGS. 5A and 5B, nanostructures 102 may be provided on the first surface 100a of the substrate region 100. The nanostructures 102 may be substantially the same as the nanostructures 102 described with reference to FIG. 24 except for their provision locations. The nanostructures 102 may be formed to extend from the first surface 100a of the substrate region 100 in a direction opposite to the third direction DR3. For brevity of explanation, 16 nanostructures 102 are illustrated. The number of nanostructures 102 may be determined as needed. Unlike those explained with reference to FIG. 24, the upper portions of the nanostructures 102 may be closer to the substrate region 100 than the lower portions. The upper portions of the nanostructures 102 may be configured so that light transmitting the substrate region 100 and incident on the top of the nanostructures 102 generates whispering gallery modes (WGM) resonance. The upper portions of the nanostructures 102 may be provided to increase the effective length of incident light transmitting the nanostructures 102 by whispering gallery mode resonance. The lower portions of the nanostructures 102 may be configured to absorb incident light reflected from the nanostructures 102 immediately adjacent to each other.

Electron-hole pairs generated by incident light in the nanostructures 102 may be configured to be transmitted in the third direction DR3 along the shape of the nanostructures 102. An electric field may be provided by a voltage applied to the floating diffusion regions 130 and the second electrode patterns 160. The direction of the electric field may be provided in the third direction DR3. The direction in which electron-hole pairs generated by incident light in the nanostructures 102 are transferred to the floating diffusion regions 130 and the second electrode patterns 160 may be substantially the same as the direction of the electric field. The electron-hole pairs generated in the nanostructures 102 may be transferred to the floating diffusion regions 130 and the second electrode patterns 160 without disappearing. The nanostructures 102 may be disposed on one side of the gate electrodes GE.

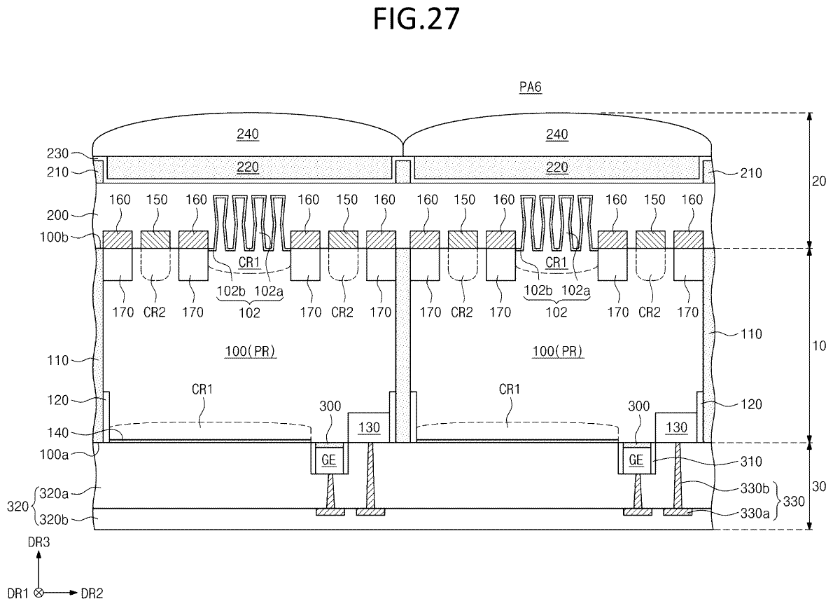

FIG. 27 is a cross-sectional view showing an image sensor according to some exemplary embodiments. For brevity of explanation, content that is substantially the same as that described with reference to FIGS. 5A and 5B and that with reference to FIG. 24 may not be described.

Referring to FIG. 27, an image sensor PA6 may be provided. Unlike those described with reference to FIGS. 5A and 5B, nanostructures 102 may be provided on the second surface 100b of the substrate region 100. The nanostructures 102 may be substantially the same as the nanostructures 102 described with reference to FIG. 24 except for their provision locations. The nanostructures 102 may be provided between second electrode patterns 160 that are immediately adjacent to each other. Accordingly, a first photoelectric conversion region CR1 may be provided between the second electrode patterns 160 that are immediately adjacent to each other. For brevity of explanation, four nanostructures 102 are illustrated between the second electrode patterns 160 immediately adjacent to each other. The number of nanostructures 102 may be determined as needed.

Electron-hole pairs generated by incident light in the nanostructures 102 may be configured to be transferred to the substrate region 100 along the nanostructures 102. An electric field may be provided by a voltage applied to the floating diffusion regions 130 and the second electrode patterns 160. For example, the electric field may be formed in a direction from the first surface 100a to the second surface 100b. The direction in which electron-hole pairs generated by incident light in the nanostructures 102 are transferred to the floating diffusion regions 130 and the second electrode patterns 160 may be substantially the same as the direction of the electric field. The electron-hole pairs generated in the nanostructures 102 of the present disclosure may be transferred to the floating diffusion regions 130 and the second electrode patterns 160 without disappearing.

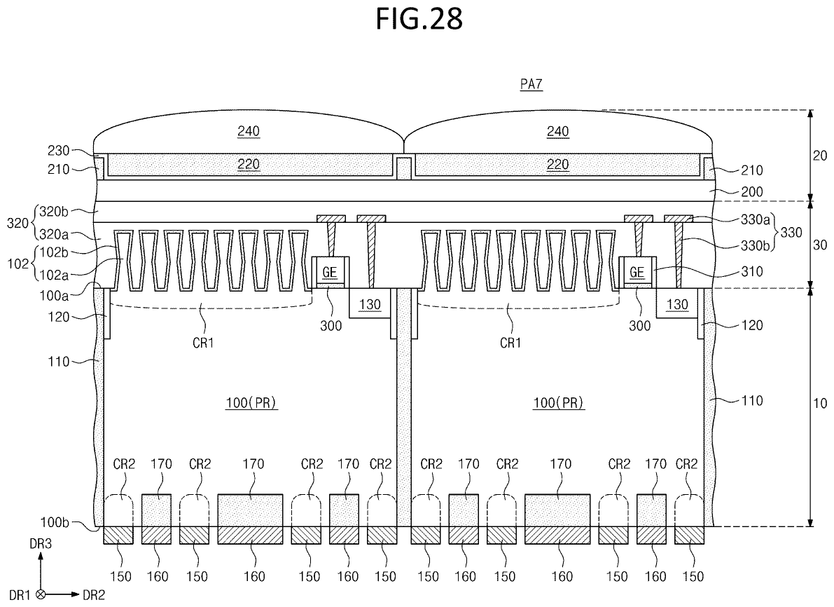

FIG. 28 is a cross-sectional view showing an image sensor according to some exemplary embodiments. For brevity of explanation, content substantially the same as that described with reference to FIG. 26 may not be described.

Referring to FIG. 28, an image sensor PA7 may be provided. The image sensor PA7 may include the element layer 10, the optical element layer 20, and the wiring layer 30. Unlike those explained with reference to FIG. 26, the wiring layer 30 may be provided between the device layer 10 and the optical element layer 20. The wiring layer 30 and the optical element layer 20 may be sequentially provided on the first surface 100a of the substrate region 100.

Electron-hole pairs generated by incident light in the nanostructures 102 may be transferred to the substrate region 100 along the nanostructures 102. An electric field may be provided by a voltage applied to the floating diffusion regions 130 and the second electrode patterns 160. For example, the electric field may be formed in a direction from the first surface 100a to the second surface 100b. The direction in which electron-hole pairs generated by incident light in the nanostructures 102 are transferred to the floating diffusion regions 130 and the second electrode patterns 160 may be substantially the same as the direction of the electric field. The electron-hole pairs generated in the nanostructures 102 of the present disclosure may be transferred to the floating diffusion regions 130 and the second electrode patterns 160 without disappearing. The nanostructures 102 may be disposed on one side of the gate electrodes GE.

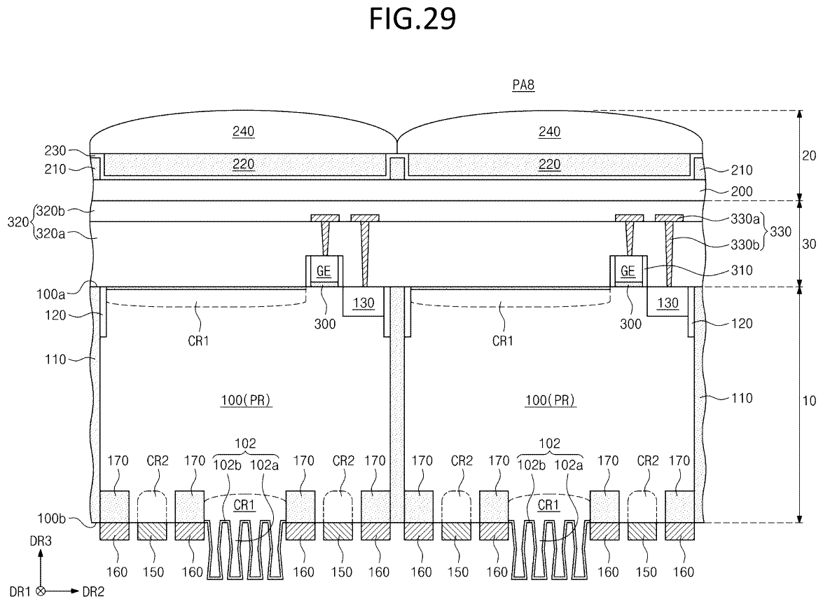

FIG. 29 is a cross-sectional view showing an image sensor according to some exemplary embodiments. For brevity of explanation, content substantially the same as that described with reference to FIG. 27 may not be described.

Referring to FIG. 29, an image sensor PA8 may be provided. The image sensor PA8 may include the element layer 10, the optical element layer 20, and the wiring layer 30. Unlike those described with reference to FIG. 27, the wiring layer 30 may be provided between the device layer 10 and the optical element layer 20. The wiring layer 30 and the optical element layer 20 may be sequentially provided on the first surface 100a of the substrate region 100.

Electron-hole pairs generated by incident light in the nanostructures 102 may be transferred to the substrate region 100 along the nanostructures 102. An electric field may be provided by a voltage applied to the floating diffusion regions 130 and the second electrode patterns 160. For example, the electric field may be formed in a direction from the first surface 100a to the second surface 100b. The direction in which electron-hole pairs generated by incident light in the nanostructures 102 are transferred to the floating diffusion regions 130 and the second electrode patterns 160 may be substantially the same as the direction of the electric field. The electron-hole pairs generated in the nanostructures 102 of the present disclosure may be transferred to the floating diffusion regions 130 and the second electrode patterns 160 without disappearing.

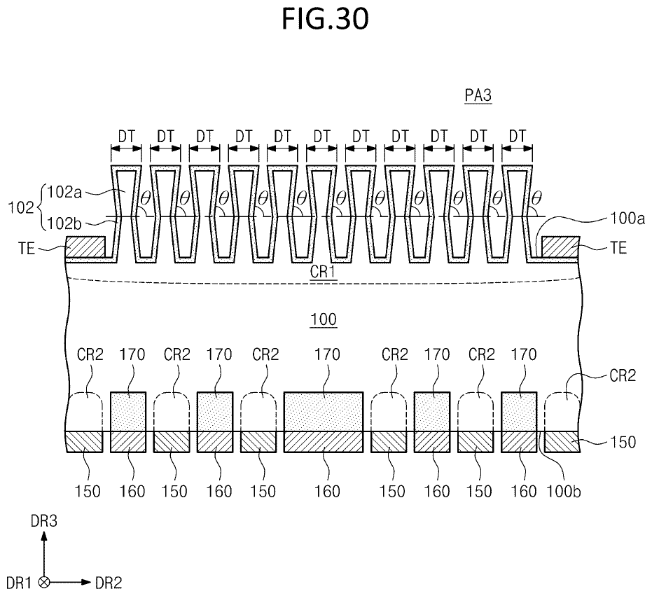

FIG. 30 is a cross-sectional view showing the image sensor of FIG. 24 to explain a method of controlling quality factors of nanostructures.

Referring to FIG. 30, nanostructures 102 may include a quality factor. For example, the nanostructures 102 including a high-quality factor may generate a whispering gallery mode resonance of high intensity with respect to incident light having a narrow wavelength range. That is, nanostructures 102 with a high-quality factor can provide high optical response to incident light having a narrow wavelength range. For example, nanostructures 102 including a low-quality factor may be provided such that the nanostructures 102 generate a whispering gallery mode resonance of low intensity for incident light having a wide wavelength range. That is, nanostructures 102 with a low-quality factor can provide high optical response to incident light having a wide wavelength range.

The quality factor of the nanostructures 102 may be determined according to the diameter DT of the top surface of the nanostructures 102 and the slope θ of the sidewall of the nanostructures 102. The smaller the diameter DT of the top surface of the nanostructures 102, the higher the quality factor. As the slope θ of the sidewall of the nanostructures 102 is increased, the quality factor may be increased. The above description of embodiments of the technical idea of the present disclosure provides examples for explaining the technical idea of the present disclosure. Therefore, the technical idea of the present disclosure is not limited to the above embodiments, and various modifications and changes can be made by combining the above embodiments by those skilled in the art within the technical idea of the present disclosure. This possibility is obvious.

What is claimed is:

1. An image sensor comprising:
a substrate region comprising a first surface and a second surface provided on opposite sides of the substrate region;
an ion implantation layer provided in the substrate region adjacent to the first surface;
a plurality of ion implantation patterns provided in the substrate region, the plurality of ion implantation patterns adjacent to the second surface;
a first photoelectric conversion region provided adjacent to the ion implantation layer;
second electrode patterns provided on the second surface such that the second electrode patterns overlap the ion implantation patterns;
first electrode patterns provided between the second electrode patterns; and
second photoelectric conversion regions provided adjacent to the first electrode patterns within the substrate region.

2. The image sensor of claim 1, further comprising an upper electrode provided on the first surface,
wherein the upper electrode is electrically connected to the ion implantation layer.

3. The image sensor of claim 1, wherein the ion implantation layer is configured to be spaced apart from the ion implantation patterns along a direction from the first surface to the second surface of the substrate region.

4. The image sensor of claim 1, wherein the first electrode patterns and the second electrode patterns comprise concentric circular patterns having different diameters, and are alternately arranged along a radial direction.

5. The image sensor of claim 1, wherein the first electrode patterns and the substrate region provide a schottky junction, and
wherein the second electrode patterns and the substrate region provide an ohmic contact.

6. The image sensor of claim 1, wherein each of the second photoelectric conversion regions is provided between the ion implantation patterns immediately adjacent to each other.

7. The image sensor of claim 1, further comprising nanostructures provided on the first surface of the substrate region,
wherein the nanostructures having an hourglass shape.

8. The image sensor of claim 7, further comprising an upper electrode provided on the first surface, the upper electrode electrically connected to the nanostructures.

9. The image sensor of claim 1, further comprising nanostructures provided on the second surface of the substrate region, the nanostructures having an hourglass shape.

10. The image sensor of claim 9, wherein the nanostructures are electrically connected to the second electrode patterns.

11. A method for manufacturing an image sensor comprising:
forming an ion implantation layer in a region adjacent to a first surface of a substrate region;
forming ion implantation patterns in a region adjacent to a second surface of the substrate region, the second surface of the substrate region located on an opposite side of the substrate region as the first surface;
forming second electrode patterns overlapping the ion implantation patterns; and
forming first electrode patterns between the second electrode patterns.

12. The method for manufacturing the image sensor of claim 11, wherein forming the ion implantation patterns comprises:
forming sacrificial patterns on the second surface; and
implanting impurities between the sacrificial patterns.

13. The method for manufacturing the image sensor of claim 11, further comprising forming a vertical nanocore on the first surface of the substrate region; and
forming a vertical nanoshell by implanting impurities into the vertical nanocore.

14. The method for manufacturing the image sensor of claim 11, further comprising: forming a vertical nanocore on the second surface of the substrate region; and
forming a vertical nanoshell by implanting impurities into the vertical nanocore.

15. An image sensor comprising:
a substrate region;
an ion implantation layer provided on an upper portion of the substrate region;
a first photoelectric conversion region provided within the substrate region by the ion implantation layer;
ion implantation patterns provided at a lower portion of the substrate region;
second electrode patterns overlapping the ion implantation patterns;
first electrode patterns provided such that the first electrode patterns are electrically spaced apart from the second electrode patterns;
second photoelectric conversion regions provided within the substrate region by the first electrode patterns; and
a top electrode provided on the upper portion of the substrate region.

16. The image sensor of claim 15, wherein, from a plan view, the first electrode patterns and the second electrode patterns are arranged radially from the center of the substrate region.

17. The image sensor of claim 15, wherein the ion implantation layer is configured to be spaced apart from the ion implantation patterns along a direction from the upper portion to the lower portion of the substrate region.

18. The image sensor of claim 15, wherein the first electrode patterns and the substrate region provide a schottky junction, and
wherein the second electrode patterns and the substrate region provide an ohmic contact.

19. The image sensor of claim 15, wherein each of the second photoelectric conversion regions is provided between the ion implantation patterns immediately adjacent to each other.

20. The image sensor of claim 15, further comprising nanostructures provided on the first surface of the substrate region, the nanostructures having an hourglass shape.
